(19) United States
(12) Patent Application Publication
(10) Pub. No.: US 2026/0215093 A1
(43) Pub. Date: Jul. 23, 2026

(54) DISPLAY DEVICE, VEHICLE AND ELECTRONIC DEVICE

(71) Applicant: Samsung Display Co., LTD., Yongin-si (KR)

(72) Inventors: Jong Hyun CHOI, Yongin-si (KR); Young Woon KHO, Yongin-si (KR); Sang Hui HAN, Yongin-si (KR)

(21) Appl. No.: 19/326,029

(22) Filed: Sep. 11, 2025

(30) Foreign Application Priority Data
Jan. 20, 2025 (KR) 10-2025-0008345

(51) Int. Cl. H10K 59/122; H10K 59/131

(52) U.S. Cl. CPC H10K 59/122; H10K 59/131

(57) ABSTRACT

Provided are provide a display device, a vehicle, and an electronic device capable of minimizing glare to a user. The display device includes a display panel, and a display driver connected to the display panel. The display panel includes a substrate, a pixel electrode on the substrate, a pixel defining layer located on the pixel electrode and having an emission area overlapping at least a part of the pixel electrode, a light emitting layer on the pixel defining layer, and a common electrode on the light emitting layer. The emission area includes a first corner having a curved shape protruding convexly toward a first side of the display panel, the first corner includes a plurality of sub-corners connected to each other, and each of the plurality of sub-corners has a curved shape protruding convexly toward the first side of the display panel.

This application claims priority to Korean Patent Application No. 10-2025-0008345, filed on Jan. 20, 2025, and all the benefits accruing therefrom under 35 U.S.C. § 119, the content of which in its entirety is herein incorporated by reference.

### BACKGROUND

### 1. Field

The present disclosure relates to a display device, and more particularly, to a display device, a vehicle, and an electronic device capable of minimizing glare to a user.

### 2. Description of the Related Art

With the advancement of an information-oriented society, increased demand is being placed for display devices capable of displaying images in various ways. A display device may be a flat panel display device such as, for example, a liquid crystal display, a field emission display and a light emitting display. A light emitting display device may include an organic light emitting display device including an organic light emitting diode element as a light emitting element or a light emitting diode display device including an inorganic light emitting diode element such as, for example, a light emitting diode (LED) as a light emitting element.

### SUMMARY

Aspects of the present disclosure provide a display device, a vehicle, and an electronic device capable of minimizing glare to a user.

According to one embodiment of the present disclosure, there is provided a display device including: a display panel; and a display driver connected to the display panel, wherein the display panel includes: a substrate; a pixel electrode on the substrate; a pixel defining layer located on the pixel electrode and having an emission area overlapping at least a part of the pixel electrode; a light emitting layer on the pixel defining layer; and a common electrode on the light emitting layer, wherein the emission area includes a first corner having a curved shape protruding convexly toward a first side of the display panel, the first corner includes a plurality of sub-corners connected to each other, and each of the plurality of sub-corners has a curved shape protruding convexly toward the first side of the display panel.

According to one embodiment of the present disclosure, there is provided a display device including: a display panel; and a display driver connected to the display panel, wherein the display panel includes: a substrate; a pixel electrode on the substrate; a pixel defining layer located on the pixel electrode and having an emission area overlapping at least a part of the pixel electrode; a light emitting layer on the pixel defining layer; a common electrode on the light emitting layer; and a pattern layer disposed directly below the pixel electrode, between the substrate and the pixel electrode, wherein the emission area includes a first corner having a curved shape protruding convexly toward a first side of the display panel, and in plan view, the pattern layer extends along a first direction perpendicular to an extension direction of the first side.

According to one embodiment of the present disclosure, there is provided a vehicle including: a driver's seat; and a display device located adjacent to the driver's seat, wherein the display device includes: a display panel; and a display driver connected to the display panel, wherein the display panel includes: a substrate; a pixel electrode on the substrate; a pixel defining layer located on the pixel electrode and having an emission area overlapping at least a part of the pixel electrode; a light emitting layer on the pixel defining layer; and a common electrode on the light emitting layer, wherein the emission area includes a first corner having a curved shape protruding convexly toward a first side of the display panel, the first corner includes a plurality of sub-corners connected to each other, and each of the plurality of sub-corners has a curved shape protruding convexly toward the first side of the display panel.

According to one embodiment of the present disclosure, there is provided a vehicle including: a seat; and a display device located adjacent to the seat, wherein the display device includes: a display panel; and a display driver connected to the display panel, wherein the display panel includes: a substrate; a pixel electrode on the substrate; a pixel defining layer located on the pixel electrode and having an emission area overlapping at least a part of the pixel electrode; a light emitting layer on the pixel defining layer; a common electrode on the light emitting layer; and a pattern layer disposed directly below the pixel electrode, between the substrate and the pixel electrode, wherein the emission area includes a first corner having a curved shape protruding convexly toward a first side of the display panel, and in plan view, the pattern layer extends along a first direction perpendicular to an extension direction of the first side.

According to one embodiment of the present disclosure, there is provided an electronic device including: a processor; a memory connected to the processor; and a display device connected to the processor, wherein the display device includes: a display panel; and a display driver connected to the display panel, wherein the display panel includes: a substrate; a pixel electrode on the substrate; a pixel defining layer located on the pixel electrode and having an emission area overlapping at least a part of the pixel electrode; a light emitting layer on the pixel defining layer; and a common electrode on the light emitting layer, wherein the emission area includes a first corner having a curved shape protruding convexly toward a first side of the display panel, the first corner includes a plurality of sub-corners connected to each other, and each of the plurality of sub-corners has a curved shape protruding convexly toward the first side of the display panel.

According to one embodiment of the present disclosure, there is provided an electronic device including: a processor; a memory connected to the processor; and a display device connected to the processor, wherein the display device includes: a display panel; and a display driver connected to the display panel, wherein the display panel includes: a substrate; a pixel electrode on the substrate; a pixel defining layer located on the pixel electrode and having an emission area overlapping at least a part of the pixel electrode; a light emitting layer on the pixel defining layer; a common electrode on the light emitting layer; and a pattern layer disposed directly below the pixel electrode, between the substrate and the pixel electrode, wherein the emission area includes a first corner having a curved shape protruding convexly toward a first side of the display panel, and in plan view, the pattern layer extends along a first direction perpendicular to an extension direction of the first side.

According to the display device, the vehicle, and the electronic device according to an embodiment, the glare to a user may be minimized.

For example, according to an embodiment, among corners of an emission area of a display panel, the corner protruding toward a first side (e.g., a side adjacent to a direction in which the user is positioned) of the display panel has the largest radius of curvature, such that the amount of scattered light reflected from the display panel and traveling toward the first side may be minimized. Accordingly, the amount of scattered light toward the user (e.g., a driver positioned in the driver's seat of the vehicle) may be minimized, such that glare to the user (e.g., the driver) may be minimized.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view illustrating a display device 10 according to an embodiment;

FIG. 2 is a block diagram illustrating a display panel and a display driver according to an embodiment;

FIG. 3 is a circuit diagram of one pixel of a display device according to an embodiment;

FIG. 4 is a cross-sectional view of a display device according to an embodiment;

FIG. 5 is a plan view of the display device according to an embodiment;

FIG. 6 is an enlarged view of area A1 of FIG. 5;

FIG. 7 is an enlarged view of the emission area according to an embodiment;

FIG. 8 is a view for describing the shape and radius of curvature of each corner of the emission area of FIG. 7;

FIG. 9 is a diagram illustrating a portion of a vehicle including the display device according to an embodiment;

FIG. 10 is an enlarged view of a portion of FIG. 9;

FIG. 11 is an enlarged view of the display device according to an embodiment;

FIG. 12 is an enlarged view of the emission area according to an embodiment;

FIG. 13 is a view for describing the shape and radius of curvature of each corner of the first emission area of FIG. 12;

FIG. 14 is an enlarged view of the emission area of the display device according to an embodiment;

FIG. 15 is a view for describing the shape and radius of curvature of each corner of the emission area of FIG. 14;

FIG. 16 is an enlarged view of the display device according to an embodiment;

FIG. 17 is an enlarged view of the emission area according to an embodiment;

FIG. 18 is a view for describing the shape and radius of curvature of each corner of the first emission area of FIG. 17;

FIG. 19 is an enlarged view of a portion of the vehicle including the display device 10 of FIGS. 16 to 18;

FIG. 20 is a plan view of the display device according to an embodiment;

FIG. 21 is a block diagram of an electronic device according to an embodiment; and

FIGS. 22 and 23 are schematic views of electronic devices according to various embodiments.

### DETAILED DESCRIPTION

Embodiments supported by the present disclosure will now be described more fully hereinafter with reference to the accompanying drawings, in which example embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will fully convey the scope of example aspects of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, and the like may be used herein to describe various elements, these elements, should not be limited by these terms. These terms may be used to distinguish one element from another element. Thus, a first element discussed below may be termed a second element without departing from teachings of one or more embodiments. The description of an element as a “first” element is not to be limited to requiring or implying the presence of a second element or other elements. The terms “first”, “second”, and the like may also be used herein to differentiate different categories or sets of elements. For conciseness, the terms “first”, “second”, and the like may represent “first-category (or first-set)”, “second-category (or second-set)”, and the like, respectively.

The term “adjacent” used herein may refer to cases in which elements are relatively close to but spaced apart from one another. In some cases, elements described as adjacent to one another may be neighboring one another but spaced apart by a predetermined distance.

The term “close to” may refer to cases in which elements are spaced apart from one another by a relatively small distance suitable for implementing aspects of the present disclosure. In some aspects, the distance may be a predetermined distance associated with implementing aspects of the present disclosure.

Features of various embodiments of the present disclosure may be combined partially or totally. As will be clearly appreciated by those skilled in the art, technically various interactions and operations are possible. Various embodiments can be practiced individually or in combination.

Hereinafter, specific example embodiments will be described with reference to the accompanying drawings.

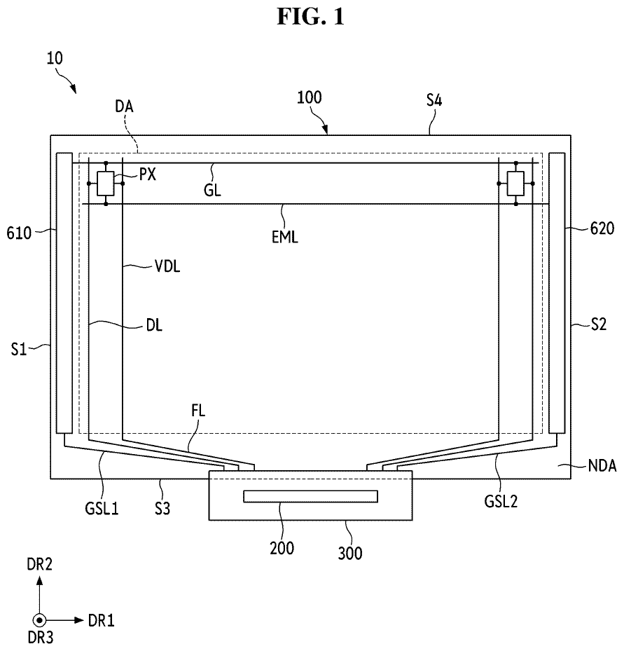

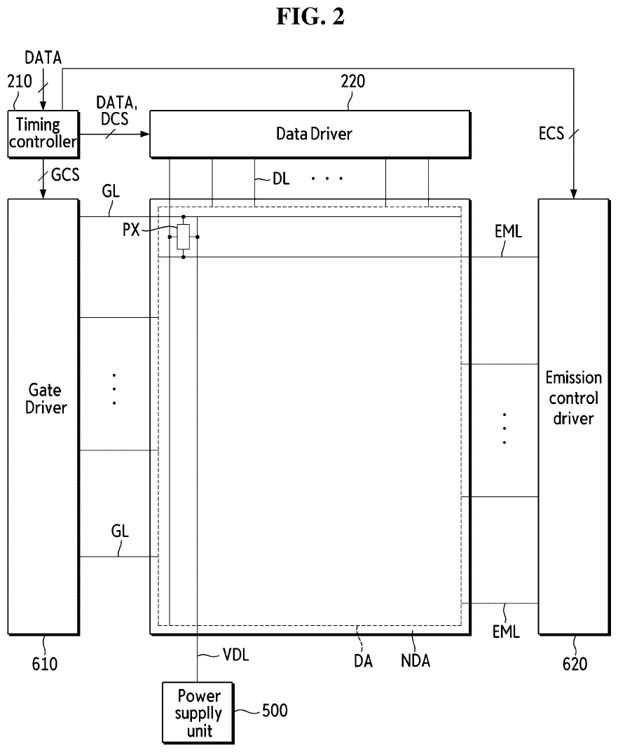

FIG. 1 is a plan view illustrating a display device 10 according to an embodiment. FIG. 2 is a block diagram illustrating a display panel and a display driver according to an embodiment.

The display device 10 may include a display panel 100, a display driver 200, a circuit board 300, and a power supply unit 500, as illustrated in FIGS. 1 and 2.

As illustrated in FIG. 1, the display panel 100 may be formed in a quadrilateral shape or quadrilateral-like planar shape. For example, the display panel 100 may include a first side, a second side, a third side, and a fourth side.

Each of the first side and the second side of the display panel 100 may extend in the second direction, and each of the third side and the fourth side of the display panel 100 may extend in the first direction.

The third side of the display panel 100 may overlap the circuit board 300. The first side of the display panel 100 may be located adjacent to an end of the third side. For example, the first side of the display panel 100 may be located between an end of the third side and an end of the fourth side. The second side of the display panel 100 may be located adjacent to the other end of the third side. For example, the second side of the display panel 100 may be located between the other end of the third side and the other end of the fourth side. The first side and the second side of the display panel 100 may face each other in the first direction, and the third side and the fourth side of the display panel 100 may face each other in the second direction.

The lengths of the facing sides of the display panel 100 may be equal to each other. For example, the first side and the second side of the display panel 100 may have the same length. In some aspects, the third side and fourth side of the display panel 100 may have the same length.

The lengths of the adjacent sides of the display panel 100 may be different from each other. For example, the length of the third side of the display panel 100 may be longer than the length of the first side of the display panel 100. In some aspects, the length of the fourth side of the display panel 100 may be longer than the length of the second side of the display panel 100. However, embodiments of the present disclosure are not limited thereto, and the length of each of the first to fourth sides may be modified in various ways.

The display panel 100 may include a display area DA and a non-display area NDA.

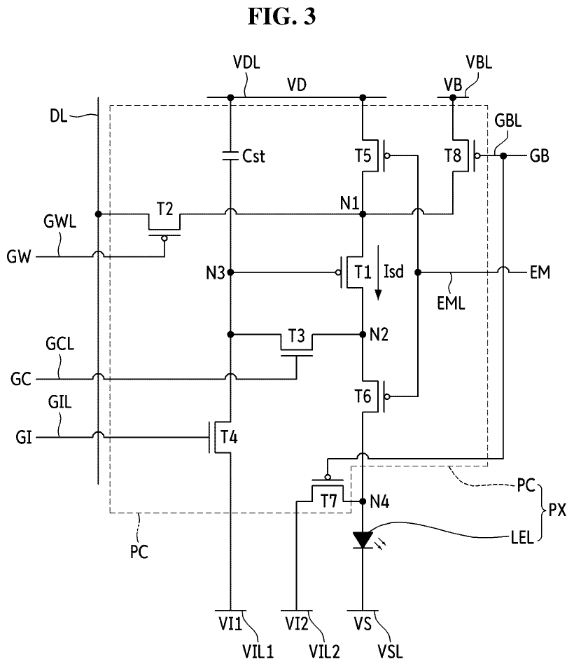

The display area DA may include a plurality of pixels PX, and a plurality of driving voltage lines VDL, a plurality of common voltage lines VSL (see FIG. 3), a plurality of gate lines GL, a plurality of emission control lines EML, and a plurality of data lines DL connected to the plurality of pixels PX.

Each of the plurality of pixels PX may be connected to the gate line GL, the data line DL, the emission control line EML, the driving voltage line VDL, and the common voltage line VSL. Each of the pixels PX may include at least one transistor, a light emitting element and a capacitor.

Each of the plurality of gate lines GL may extend in the first direction DR1 and may be spaced apart from each other in the second direction DR2 intersecting the first direction DR1. The gate lines GL may be arranged along the second direction DR2. The gate lines GL may sequentially supply gate signals to the plurality of pixels PX.

The emission lines EML may each extend in the first direction DR1 and may be spaced apart from each other in the second direction DR2. The emission line EML may be arranged along the second direction DR2. The emission lines EML may sequentially supply an emission signal to the plurality of pixels PX.

The data lines DL may extend in the second direction DR2 and may be spaced apart from each other in the first direction DR1. The data lines DL may be arranged along the first direction DR1. The data lines DL may supply data voltages to the plurality of pixels PX. The data voltage may determine the luminance of each of the pixels PX.

The driving voltage lines VDL may extend in the second direction DR2 and may be spaced apart from each other in the first direction DR1. The driving voltage lines VDL may be arranged along the first direction DR1. The driving voltage lines VDL may supply a first driving voltage to the plurality of pixels PX. The first driving voltage may be a high potential voltage for driving the light emitting elements of the pixels PX.

The non-display area NDA may surround the display area DA. The non-display area NDA may include a gate driver 610, an emission driver 620, fan-out lines FL, a first gate control line GSL1, and a second gate control line GSL2.

The fan-out lines FL may extend from the display driver 200 to the display area DA. The fan-out lines FL may supply the data voltage received from the display driver 200 to the plurality of data lines DL. The fan-out lines FL may be connected to the display driver 200 through the circuit board 300.

The first gate control line GSL1 may extend from the display driver 200 to the gate driver 610. The first gate control line GSL1 may supply a gate control signal GCS received from the display driver 200 to the gate driver 610. The first gate control lines GSL1 may be connected to the display driver 200 through the circuit board 300.

The second gate control line GSL2 may extend from the display driver 200 to the emission driver 620. The second gate control line GSL2 may supply an emission control signal ECS received from the display driver 200 to the emission driver 620.

The display driver 200 may include a timing controller 210 and a data driver 220.

The timing controller 210 may receive digital video data DATA and timing signals from the circuit board 300. The timing controller 210 may generate, based on the timing signals, a data control signal DCS to control the operation timing of the data driver 220, the gate control signal GCS to control the operation timing of the gate driver 610, and the emission control signal ECS to control the operation timing of the emission driver 620. The timing controller 210 may supply the gate control signal GCS to the gate driver 610 through the first gate control line GSL1. The timing controller 210 may supply the emission control signal ECS to the emission driver 620 through the second gate control line GSL2. The timing controller 210 may supply the digital video data DATA and the data control signal DCS to the data driver 220.

The data driver 220 may convert the digital video data DATA into analog data voltages and supply them to the data lines DL through the fan-out lines FL. The gate signals of the gate driver 610 may select the pixels PX to which the data voltage is supplied, and the selected pixels PX may receive the data voltage through the data lines DL.

The power supply unit 500 may be located on the circuit board 300 to supply a power voltage to the display driver 200 and the display panel 100. The power supply unit 500 may generate and supply a driving voltage to the driving voltage line VDL, generate and supply an initialization voltage to the initialization voltage line, and generate and supply a common voltage to the common electrode common to the light emitting elements of the plurality of pixels.

The gate driver 610 may be located at one external side of the display area DA or at one side of the non-display area NDA. The emission driver 620 may be located at the other external side of the display area DA or at the other side of the non-display area NDA. However, embodiments of the present disclosure are not limited thereto. As another example, the gate driver 610 and the emission driver 620 may be located at any one of one side and the other side of the non-display area NDA.

The gate driver 610 may include a plurality of transistors for generating gate signals based on the gate control signal GCS. The emission driver 620 may include a plurality of transistors for generating emission signals based on the emission control signal ECS. For example, the transistors of the gate driver 610 and the transistors of the emission driver 620 may be formed in the same layer as the transistors of each of the pixels PX. The gate driver 610 may supply the gate signals to the gate lines GL, and the emission driver 620 may supply the emission signals to the emission lines EML.

FIG. 3 is a circuit diagram of one pixel of a display device according to an embodiment. For example, FIG. 3 may be an equivalent circuit diagram for the pixel PX of FIG. 1.

The pixel SP may be connected to a first gate line GWL, a second gate line GCL, a third gate line GIL, a fourth gate line GBL, the emission control line EML, the data line DL, the driving voltage line VDL, a common voltage line VSL, a first initialization voltage line VIL1, and a second initialization voltage line VIL2.

The pixel PX may include a pixel circuit PC and the light emitting element ED. The pixel circuit PC may include a first transistor T1, a second transistor T2, a third transistor T3, a fourth transistor T4, a fifth transistor T5, a sixth transistor T6, a seventh transistor T7, an eighth transistor T8, and a capacitor Cst.

The first transistor T1 may include a gate electrode, a source electrode, and a drain electrode. The first transistor T1 may control a source-drain current (hereinafter, a driving current) according to the data voltage applied to the gate electrode. The driving current (e.g., Isd) flowing through a channel region of the first transistor T1 may be proportional to the square of a difference between the threshold voltage Vth and the voltage Vsg between the source electrode and the gate electrode of the first transistor T1 (Isd=k×(Vsg−Vth)²). Here, k is a proportional coefficient determined by the structure and physical characteristics of the first transistor T1, Vsg is a source-gate voltage of the first transistor T1, and Vth is a threshold voltage of the first transistor T1.

The light emitting element ED may emit light by receiving the driving current Isd. The emission amount or the luminance of the light emitting element ED may be proportional to the magnitude of the driving current Isd.

The light emitting element ED may be an organic light emitting diode including a first electrode (e.g., anode electrode or pixel electrode), a second electrode (e.g., cathode electrode or common electrode), and an organic light emitting layer located between the first and second electrodes. In another example, the light emitting element ED may be an inorganic light emitting element including a first electrode, a second electrode, and an inorganic semiconductor located between the first electrode and the second electrode. For still another example, the light emitting element ED may be a quantum dot light emitting element including a first electrode, a second electrode, and a quantum dot light emitting layer located between the first electrode and the second electrode. For still another example, the light emitting element ED may be a micro light emitting diode.

The first electrode of the light emitting element ED may be electrically connected to the fourth node N4. The first electrode of the light emitting element ED may be connected to the drain electrode of the sixth transistor T6 and the source electrode of the seventh transistor T7 through the fourth node N4. The second electrode of the light emitting element ED may be connected to the common voltage line VSL. The second electrode of the light emitting element ED may receive the common voltage VS (e.g., low potential voltage) from the common voltage line VSL.

The second transistor T2 may be turned on by a first gate signal GW of the first gate line GWL to electrically connect the data line DL with a first node N1 that is the source electrode of the first transistor T1. The second transistor T2 may be turned on according to the first gate signal to supply the data voltage to the first node N1. The gate electrode of the second transistor T2 may be electrically connected to the first gate line GWL, the source electrode of the second transistor T2 may be electrically connected to the data line DL, and the drain electrode of the second transistor T2 may be electrically connected to the first node N1.

The third transistor T3 may be turned on by a second gate signal GC of the second gate line GCL to electrically connect the second node N2, which is the drain electrode of the first transistor T1, to the third node N3, which is the gate electrode of the first transistor T1. The third transistor T3 may be connected between the third node N3 and the second node N2. For example, the gate electrode of the third transistor T3 may be electrically connected to the second gate line GCL, the source electrode of the third transistor T3 may be electrically connected to the third node N3, and the drain electrode of the third transistor T3 may be electrically connected to the second node. The third transistor T3 may be turned on by a second gate signal of the second gate line GCL to electrically connect the second node N2, which is the drain electrode of the first transistor T1, to the third node N3, which is the gate electrode of the first transistor T1.

The fourth transistor T4 may be turned on by a third gate signal GI of the third gate line GIL to electrically connect the third node N3, which is the gate electrode of the first transistor T1, to the first initialization voltage line VIL1. The fourth transistor T4 may be connected in series between the third node N3 and the first initialization voltage line VIL1. For example, the gate electrode of the fourth transistor T4 may be electrically connected to the third gate line GIL, the source electrode of the fourth transistor T4 may be electrically connected to the third node N3, and the drain electrode of the fourth transistor T4 may be electrically connected to the first initialization voltage line VIL1.

The fifth transistor T5 may be turned on by the emission signal EM of the emission line EML to electrically connect the driving voltage line VDL with the first node N1 that is the source electrode of the first transistor T1. The gate electrode of the fifth transistor T5 may be electrically connected to the emission control line EML, the source electrode of the fifth transistor T5 may be electrically connected to the driving voltage line VDL, and the drain electrode of the fifth transistor T5 may be electrically connected to the first node N1.

The sixth transistor T6 may be turned on by the emission signal EM of the emission line EML to electrically connect the second node N2 that is the drain electrode of the first transistor T1 with the fourth node N4 that is the first electrode of the light emitting element ED. The gate electrode of the sixth transistor T6 may be electrically connected to the emission control line EML, the source electrode of the sixth transistor T6 may be electrically connected to the second node N2, and the drain electrode of the sixth transistor T6 may be electrically connected to the fourth node N4. In an example in which all of the fifth transistor T5, the first transistor T1, and the sixth transistor T6 are turned on, the driving current may be supplied to the light emitting element ED.

The seventh transistor T7 may be turned on by a fourth gate signal GB of the fourth gate line GBL to electrically connect the fourth node N4 that is the first electrode of the light emitting element ED with the second initialization voltage line VIL2. By turning on the seventh transistor T7 based on the fourth gate signal, the first electrode of the light emitting element ED may be discharged to a second initialization voltage V2. The gate electrode of the seventh transistor T7 may be electrically connected to the fourth gate line GBL, the source electrode of the seventh transistor T7 may be electrically connected to the fourth node N4, and the drain electrode of the seventh transistor T7 may be electrically connected to the second initialization voltage line VIL2. The second initialization voltage line VIL2 may transmit a second initialization voltage VI2.

The eighth transistor T8 may be turned on by the fourth gate signal GB of the fourth gate line GBL to electrically connect the bias voltage line VBL with the first node N1 that is the source electrode of the first transistor T1. The eighth transistor T8 may be turned on according to the fourth gate signal GB to supply a bias voltage VB to the first node N1. The eighth transistor T8 may improve hysteresis of the first transistor T1 by supplying the bias voltage VB to the source electrode of the first transistor T1. The gate electrode of the eighth transistor T8 may be electrically connected to the fourth gate line GBL, the source electrode of the eighth transistor T8 may be electrically connected to the bias voltage line VBL, and the drain electrode of the eighth transistor T8 may be electrically connected to the first node N1.

Each of the first transistor T1, the second transistor T2, the fifth transistor T5, the sixth transistor T6, the seventh transistor T7, and the eighth transistor T8 may include a silicon-based active layer. For example, each of the first transistor T1, the second transistor T2, the fifth transistor T5, the sixth transistor T6, the seventh transistor T7, and the eighth transistor T8 may be a p-type transistor including an active layer containing low temperature polycrystalline silicon (LTPS). The active layer containing low temperature polycrystalline silicon may have high electron mobility and excellent turn-on characteristics. Accordingly, in the display device 10, since the transistors having excellent turn-on characteristics are included, it is possible to stably and efficiently drive the plurality of pixels PX. Each of the first transistor T1, the second transistor T2, the fifth transistor T5, the sixth transistor T6, the seventh transistor T7, and the eighth transistor T8 may output a current flowing into the source electrode to the drain electrode based on a gate low voltage applied to the gate electrode.

The third transistor T3 and the fourth transistor T4 may be n-type transistors including an oxide-based active layer. The transistor including the oxide-based active layer may have a coplanar structure in which a gate electrode is located thereon. The transistor including the oxide-based active layer may output a current flowing into the drain electrode to the source electrode based on a gate high voltage applied to the gate electrode.

The capacitor Cst may be electrically connected between the third node N3 that is the gate electrode of the first transistor T1 and the driving voltage line VDL. For example, the first electrode of the capacitor Cst may be electrically connected to the third node N3, and the second electrode of the capacitor Cst may be electrically connected to the driving voltage line VDL, such that a potential difference between the driving voltage line VDL and the gate electrode of the first transistor T1 may be maintained.

In some embodiments, the pixels PX may include a plurality of pixels that provide light of different colors (or wavelengths). For example, the pixels may include a first pixel providing light of a first color, a second pixel providing light of a second color, and a third pixel providing light of a third color. To this end, according to an embodiment, the first pixel may include a first light emitting element that provides light of the first color, the second pixel may include a second light emitting element that provides light of the second color, and the third pixel may include a third light emitting element that provides light of the third color. Here, the first color may be light in a red wavelength band, the second color may be light in a green wavelength band, and the third color may be light in a blue wavelength band. However, embodiments of the present disclosure are not limited thereto, and the first color, the second color, and the third color may have various colors of different wavelengths.

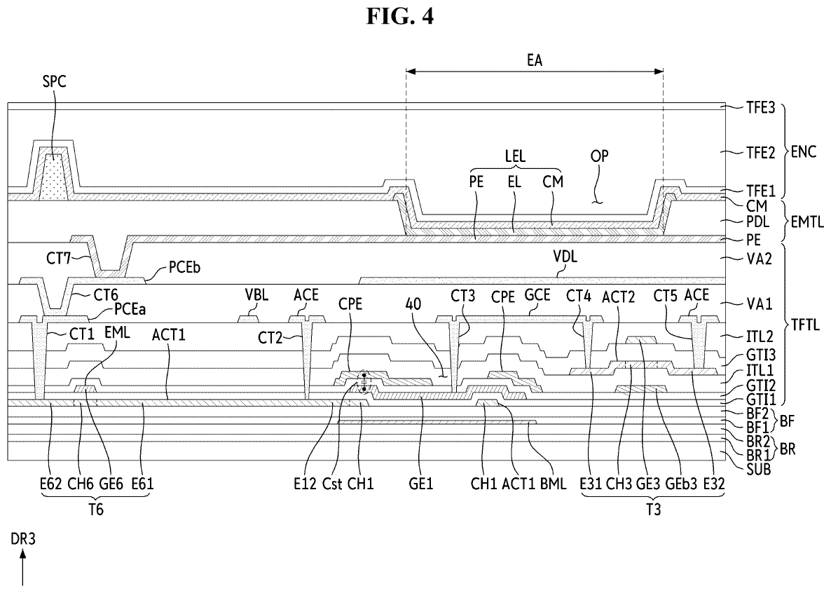

FIG. 4 is a cross-sectional view of a display device according to an embodiment. For example, FIG. 4 may be a cross-sectional view of a part of the pixel of FIG. 1.

As illustrated in FIG. 4, the display panel 100 of the display device 10 may include a substrate SUB, a barrier layer BR, a thin film transistor layer TFTL, a light emitting element layer EMTL, and an encapsulation layer ENC. The barrier layer BR, the thin film transistor layer TFTL, the light emitting element layer EMTL, and the encapsulation layer ENC may be sequentially located on the substrate SUB along the third direction DR3.

The substrate SUB may be a rigid substrate or a flexible substrate which can be bent, folded or rolled. The substrate SUB may include an insulating material such as, for example, glass, quartz, or a polymer resin. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. Alternatively, the substrate SUB may include a metal material.

As illustrated in FIG. 4, the barrier layer BR may be located on the substrate SUB. The barrier layer BR may be located on the entire surface of the substrate SUB. The barrier layer BR may be a film which may protect the transistors T1 to T8 of the thin film transistor layer TFTL and a light emitting layer EL of the light emitting element layer EMTL from moisture permeating through the substrate SUB which is susceptible to moisture permeation. The barrier layer BR may include a plurality of inorganic films that are alternately stacked. For example, the barrier layer BR may include multiple films (e.g., a first barrier layer BR1 and a second barrier layer BR2) in which one or more inorganic films of a silicon nitride layer, a silicon oxynitride layer, a silicon oxide layer, a titanium oxide layer and an aluminum oxide layer are alternately stacked.

As illustrated in FIG. 4, a first pattern layer may be located on the barrier layer BR. For example, the light blocking layer BML may be located on the barrier layer BR. The light blocking layer BML may be located on the barrier layer BR and cover an overlapping region (e.g., the first channel region CH1) between the first gate electrode GE1 and the first active layer ACT1. In other words, the light blocking layer BML may be located on the barrier layer BR and overlap the channel region CH1 of the first transistor T1 which is the driving transistor. The light blocking layer BML may include, for example, a metallic material such as, for example, chromium (Cr) or molybdenum (Mo), black ink, black dye, or the like. In an example in which the light blocking layer BML includes a metallic material, the light blocking layer BML may be supplied with a constant power source. In this way, the light blocking layer BML is not electrically floating, and the transistor (e.g., the first transistor T1) on the light blocking layer BML may have its electrical characteristics stabilized.

As illustrated in FIG. 4, a buffer layer BF may be located on the light blocking layer BML. The buffer layer BF may be located on the entire surface of the substrate SUB including the barrier layer BR. The buffer layer BF may be a film which may protect the transistors T1 to T8 of the thin film transistor layer TFTL and a light emitting layer EL of the light emitting element layer EMTL from moisture permeating through the substrate SUB which is susceptible to moisture permeation. The buffer layer BF may include a plurality of inorganic films that are alternately stacked. For example, the buffer layer BF may include multiple films (e.g., a first buffer layer BF1 and a second buffer layer BF2 in which one or more inorganic films of a silicon nitride layer, a silicon oxynitride layer, a silicon oxide layer, a titanium oxide layer and an aluminum oxide layer are alternately stacked.

The second pattern layer may be located on the buffer layer BF. For example, the first active layer ACT1 may be located on the barrier layer BR. As illustrated in FIG. 4, the first active layer ACT1 may include the first channel region CH1 of the first transistor T1, the second electrode E12 of the first transistor T1, the first channel region CH1 of the first transistor T1, the first electrode E61 of the sixth transistor T6, the second electrode E62 of the sixth transistor T6, and the sixth channel region CH6 of the sixth transistor T6. The first active layer ACT1 may be an active layer containing low temperature polycrystalline silicon (LTPS).

A first gate insulating layer GTI1 may be located on the second pattern layer. For example, as illustrated in FIG. 4, the first gate insulating layer GTI1 may be located on the first active layer ACT1. In this case, the first gate insulating layer GTI1 may be located on the entire surface of the substrate SUB including the first active layer ACT1. The first gate insulating layer GTI1 may include at least one of tetraethylorthosilicate (TEOS), silicon nitride (SiNx), or silicon oxide (SiO₂). For example, the first gate insulating layer GTI1 may have a double-film structure in which a silicon nitride film having a thickness of 40 nm and a tetraethylorthosilicate film having a thickness of 80 nm are sequentially stacked.

A third pattern layer may be located on the first gate insulating layer GTI1. For example, the second gate electrode GE2, the first gate electrode GE1, the eighth gate electrode GE8, the emission control line EML, the fifth gate electrode GE5, and the sixth gate electrode GE6 may be located on the first gate insulating layer GTI1. FIG. 4 illustrates an example in which the first gate electrode GE1, the sixth gate electrode GE6, and the emission control line EML are located on the first gate insulating layer GTI1. The first gate electrode GE1 may be located on the first gate insulating layer GTI1 and overlap the first channel region CH1 of the first active layer ACT1. The sixth gate electrode GE6 of the emission control line EML may be located on the first gate insulating layer GTI1 and overlap the sixth channel region CH6 of the first active layer ACT1. The third pattern layer may include at least one of molybdenum (Mo), copper (Cu), aluminum, or titanium (Ti), and may be formed as a single layer or multiple layers. For example, the first gate electrode GE1 may be formed as a triple film including a titanium film, an aluminum film, and a titanium film located sequentially on the first gate insulating layer GTI1 along the third direction DR3.

A second gate insulating layer GTI2 may be located on the third pattern layer. For example, as illustrated in FIG. 4, the second gate insulating layer GTI2 may be located on the first gate electrode GE1, the sixth gate electrode GE6, and the emission control line EML. In this case, the second gate insulating layer GTI2 may be located on the entire surface of the substrate SUB including the first gate electrode GE1, the sixth gate electrode GE6, and the emission control line EML. The second gate insulating layer GTI2 may include the same material and structure as the first gate insulating layer GTI1 described herein.

A fourth pattern layer may be located on the second gate insulating layer GTI2. For example, the fourth counter gate electrode GEb4, the third counter gate electrode GEb3, and the capacitor electrode CPE may be located on the second gate insulating layer GTI2. FIG. 4 illustrates an example in which the capacitor electrode CPE and the third counter gate electrode GEb3 are located on the second gate insulating layer GTI2. The capacitor electrode CPE may be located on the second gate insulating layer GTI2 and overlap the first gate electrode GE1. The capacitor Cst may be formed between the capacitor electrode CPE and the first gate electrode GE1. The fourth pattern layer may have the same material or structure as the third pattern layer described herein.

A first interlayer insulating layer ITL1 may be located on the fourth pattern layer. For example, as illustrated in FIG. 4, the first interlayer insulating layer ITL1 may be located on the capacitor electrode CPE and the third counter gate electrode GEb3. In this case, the first interlayer insulating layer ITL1 may be located on the entire surface of the substrate SUB including the capacitor electrode CPE and the third counter gate electrode GEb3. The first interlayer insulating layer ITL1 may include an inorganic film, for example, a silicon nitride layer, a silicon oxynitride layer, a silicon oxide layer, a titanium oxide layer, or an aluminum oxide layer. In some embodiments, the first interlayer insulating layer ITL1 may include a plurality of inorganic films.

A fifth pattern layer may be located on the first interlayer insulating layer ITL1. For example, the second active layer ACT2 may be located on the first interlayer insulating layer ITL1. As illustrated in FIG. 4, the second active layer ACT2 may be located on the first interlayer insulating layer ITL1 and overlap the third counter gate electrode GEb3. The second active layer ACT2 may include the first electrode E31 of the third transistor T3, the second electrode E32 of the third transistor T3, and the third channel region CH3 of the third transistor T3. The third channel region CH3 of the second active layer ACT2 may overlap the third counter gate electrode GEb3. The second active layer ACT2 may be an oxide-based active layer. For example, the second active layer ACT2 may be an oxide semiconductor containing indium-gallium-zinc oxide (IGZO) or indium-gallium-zinc-tin oxide (IGZTO).

A third gate insulating layer GTI3 may be located on the fifth pattern layer. For example, as illustrated in FIG. 4, the third gate insulating layer GTI3 may be located on the second active layer ACT2. The third gate insulating layer GTI3 may be located on the entire surface of the substrate SUB including the second active layer ACT2. The third gate insulating layer GTI3 may have the same material and structure as the first gate insulating layer GTI1 described herein.

A sixth pattern layer may be located on the third gate insulating layer GTI3. For example, the fourth gate electrode GE4 and the third gate electrode GE3 may be located on the third gate insulating layer GTI3. FIG. 4 illustrates an example in which the third gate electrode GE3 is located on the third gate insulating layer GTI3. The third gate electrode GE3 may be located such that the gate electrode GE3 overlaps the third channel region CH3 of the second active layer ACT2. The sixth pattern layer may have the same material or structure as the third pattern layer described herein.

A second interlayer insulating layer ITL2 may be located on the sixth pattern layer. For example, as illustrated in FIG. 4, the second interlayer insulating layer ITL2 may be located on the third gate electrode GE3. The second interlayer insulating layer ITL2 may be located on the entire surface of the substrate SUB including the third gate electrode GE3. The second interlayer insulating layer ITL2 may have the same material and structure as the first interlayer insulating layer ITL1 described herein.

A seventh pattern layer may be located on the second interlayer insulating layer ITL2. For example, the first initialization voltage line VIL1, the third gate line GIL, the data connection electrode DCE, the first gate line GWL, the second gate line GCL, the gate connection electrode GCE, the active connection electrode ACE, the bias voltage line VBL, the capacitor connection electrode CCE, the lower pixel connection electrode PCEa, the fourth gate line EBL, and the second initialization voltage line VIL2 may be located on the second interlayer insulating layer ITL2. FIG. 4 illustrates an example in which the gate connection electrode GCE, the active connection electrode ACE, the bias voltage line VBL, and the lower pixel connection electrode PCEa are located on the second interlayer insulating layer ITL2. The lower pixel connection electrode PCEa may be connected to the second electrode E62 of the sixth transistor T6 through a first contact hole CT1 penetrating the second interlayer insulating layer ITL2, the third gate insulating layer GTI3, the first interlayer insulating layer ITL1, the second gate insulating layer GTI2, and the first gate insulating layer GTI1. The active connection electrode ACE may be connected to the second electrode E12 of the first transistor T1 and the first electrode E61 of the sixth transistor T6 through a second contact hole CT2 penetrating the second interlayer insulating layer ITL2, the third gate insulating layer GTI3, the first interlayer insulating layer ITL1, the second gate insulating layer GTI2, and the first gate insulating layer GTI1. Further, the active connection electrode ACE may be connected to the second electrode E32 of the third transistor T3 through a fifth contact hole CT5 penetrating the second interlayer insulating layer ITL2 and the third gate insulating layer GTI3. The gate connection electrode GCE may be connected to the first gate electrode GE1 through a third contact hole CT3 penetrating the second interlayer insulating layer ITL2, the third gate insulating layer GTI3, the first interlayer insulating layer ITL1, the hole 40 of the capacitor electrode CPE, and the second gate insulating layer GTI2. Further, the gate connection electrode GCE may be connected to the first electrode E31 of the third transistor T3 through a fourth contact hole CT4 penetrating the second interlayer insulating layer ITL2 and the third gate insulating layer GTI3. The seventh pattern layer may have the same material or structure as the third pattern layer described herein.

A first planarization layer VA1 may be located on the seventh pattern layer. For example, the first planarization layer VA1 may be located on the gate connection electrode GCE, the active connection electrode ACE, the bias voltage line VBL, and the lower pixel connection electrode PCEa. The first planarization layer VA1 may be located on the entire surface of the substrate SUB including the gate connection electrode GCE, the active connection electrode ACE, the bias voltage line VBL, and the lower pixel connection electrode PCEa. The first planarization layer VA1 may include an organic film such as, for example, acryl resin, epoxy resin, phenolic resin, polyamide resin, polyimide resin and the like.

An eighth pattern layer may be located on the first planarization layer VA1. For example, the first data line DL1, the driving voltage line VDL, and the upper pixel connection electrode PCEb may be located on the first planarization layer VA1. FIG. 4 illustrates an example in which the driving voltage line VDL and the upper pixel connection electrode PCEb are located on the first planarization layer VA1. The upper pixel connection electrode PCEb may be connected to the lower pixel connection electrode PCEa through a sixth contact hole CT6 penetrating the first planarization layer VA1. The eighth pattern layer may have the same material or structure as the third pattern layer described herein.

A second planarization layer VA2 may be located on the eighth pattern layer. For example, the second planarization layer VA2 may be located on the driving voltage line VDL and the upper pixel connection electrode PCEb. The second planarization layer VA2 may be located on the entire surface of the substrate SUB including the driving voltage line VDL and the upper pixel connection electrode PCEb. The second planarization layer VA2 may have the same material and structure as the first planarization layer VA1 described herein.

A ninth pattern layer may be located on the second planarization layer VA2. For example, as illustrated in FIG. 4, the light emitting element layer EMTL including the ninth pattern layer may be located on the second planarization layer VA2. For example, as illustrated in FIG. 4, the pixel electrode PE may be located on the second planarization layer VA2, as the ninth pattern layer. The pixel electrode PE may be connected to the upper pixel connection electrode PCEb through a seventh contact hole CT7 penetrating the second planarization layer VA2.

The aforementioned light emitting element layer EMTL may further include the light emitting element LEL and a pixel defining layer PDL in addition to the aforementioned ninth pattern layer.

The light emitting element LEL may include the pixel electrode PE, the light emitting layer EL, and the common electrode CM. An emission area EA, in which the pixel electrode PE, the light emitting layer EL, and the common electrode CM are sequentially stacked, indicates an area in which holes from the pixel electrode PE and electrons from the common electrode CM are combined with each other in the light emitting layer to emit light. In this case, the pixel electrode PE may be the anode electrode (or first electrode) of the light emitting element LEL, and the common electrode CM may be the cathode electrode (or second electrode) of the light emitting element LEL.

In a top emission structure that emits light toward the common electrode CM with respect to the light emitting layer EL, the pixel electrode PE may be formed as a single layer of molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and ITO, an APC alloy, or a stacked structure (ITO/APC/ITO) of APC alloy and ITO to increase the reflectivity. The APC alloy is an alloy of silver (Ag), palladium (Pd) and copper (Cu).

The pixel defining layer PDL may serve to define the emission areas EA of the pixels PX. To this end, the pixel defining layer PDL may be located such that the pixel defining layer PDL exposes a partial area of the pixel electrode PE on the second planarization layer VA2. The pixel defining layer PDL may cover an edge of the pixel electrode PE. In some embodiments, the pixel defining layer PDL may be located within the seventh contact hole CT7 penetrating the second planarization layer VA2. Accordingly, the seventh contact hole CT7 penetrating the second planarization layer VA2 may be filled by the pixel defining layer PDL. The pixel defining layer PDL may be formed as an organic film such as, for example, acryl resin, epoxy resin, phenolic resin, polyamide resin, polyimide resin and the like.

As illustrated in FIG. 4, a spacer SPC may be located on the pixel defining layer PDL. The spacer SPC may serve to support a mask during a process of manufacturing the light emitting layer EL. The spacer SPC may be formed as an organic film such as, for example, acryl resin, epoxy resin, phenolic resin, polyamide resin, polyimide resin and the like.

The light emitting layer EL may be formed on the pixel electrode PE. The light emitting layer EL may include an organic material to emit light in a selected color. For example, the light emitting layer EL may include a hole transporting layer, an organic material layer, and an electron transporting layer. The organic material layer may include a host and a dopant. The organic material layer may include a material that emits selected light, and the organic material layer may be formed using a phosphorescent material or a fluorescent material.

The aforementioned light emitting element LEL may be provided for each pixel PX. For example, a first pixel may include a first light emitting element, a second pixel may include a second light emitting element, and a third pixel may include a third light emitting element. The first light emitting element, the second light emitting element, and the third light emitting element may provide light of different colors. For example, the first light emitting element may emit light of a first color, the second light emitting element may emit light of a second color, and the third light emitting element may emit light of a third color.

For example, the organic material layer of the first light emitting layer of the first emission area emitting the light of the first color may be a phosphorescent material including a host material including carbazole biphenyl (CBP) or mCP (1,3-bis(carbazol-9-yl), and a dopant including at least one selected from the group consisting of PIQIr(acac) (bis(1-phenylisoquinoline)acetylacetonate iridium), PQIr(acac)(bis(1-phenylquinoline)acetylacetonate iridium), PQIr(tris(1-phenylquinoline)iridium)) and PtOEP (octaethylporphyrin platinum). Alternatively, the organic material layer of the first light emitting layer of the first emission area may be a fluorescent material including PBD:Eu(DBM)3(Phen) or Perylene, but embodiments of the present disclosure are not limited thereto.

The organic material layer of the second light emitting layer of the second emission area emitting the light of the second color may be a phosphorescent material including a host material including CBP or mCP, and a dopant material including Ir(ppy)3(fac tris(2-phenylpyridine)iridium. Alternatively, the organic material layer of the second light emitting layer of the second emission area emitting the light of the second color may be a fluorescent material including tris(8-hydroxyquinolino)aluminum (Alq3), but embodiments of the present disclosure are not limited thereto.

The organic material layer of the light emitting layer of the third emission area emitting the light of the third color may be a phosphorescent material including a host material including CBP or mCP, and a dopant material including (4,6-F2ppy)2Irpic or L2BD111, but embodiments of the present disclosure are not limited thereto.

The common electrode CM may be located on the first, second, and third light emitting layers (e.g., EL). The common electrode CM may be located to cover the first, second, and third light emitting layers. The common electrode CM may be a common layer commonly located in the first to third light emitting layers. A capping layer may be formed on the common electrode CM.

In the top emission structure, the common electrode CM may include a transparent conductive material (TCO) such as, for example, ITO or IZO capable of transmitting light or a semi-transmissive conductive material such as, for example, magnesium (Mg), silver (Ag), or an alloy of magnesium (Mg) and silver (Ag). In an example in which the common electrode CM includes a semi-transmissive conductive material, the light emission efficiency can be increased due to a micro-cavity effect.

The encapsulation layer ENC may be formed on the light emitting element layer EMTL. The encapsulation layer ENC may include at least one inorganic film TFE1 and TFE3 to prevent oxygen or moisture from permeating into the light emitting element layer EMTL. In some aspects, the encapsulation layer ENC may include at least one organic film to protect the light emitting element layer EMTL from foreign substances such as, for example, dust. For example, the encapsulation layer ENC may include a first encapsulation inorganic film TFE1, an encapsulation organic film TFE2, and a second encapsulation inorganic film TFE3.

The first encapsulation inorganic film TFE1 may be located on the common electrode CM, the encapsulation organic film TFE2 may be located on the first encapsulation inorganic film TFE1, and the second encapsulation inorganic film TFE3 may be located on the encapsulation organic film TFE2. The first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer and an aluminum oxide layer are alternately stacked. The encapsulation organic film TFE2 may be an organic film such as, for example, acryl resin, epoxy resin, phenolic resin, polyamide resin, polyimide resin or the like.

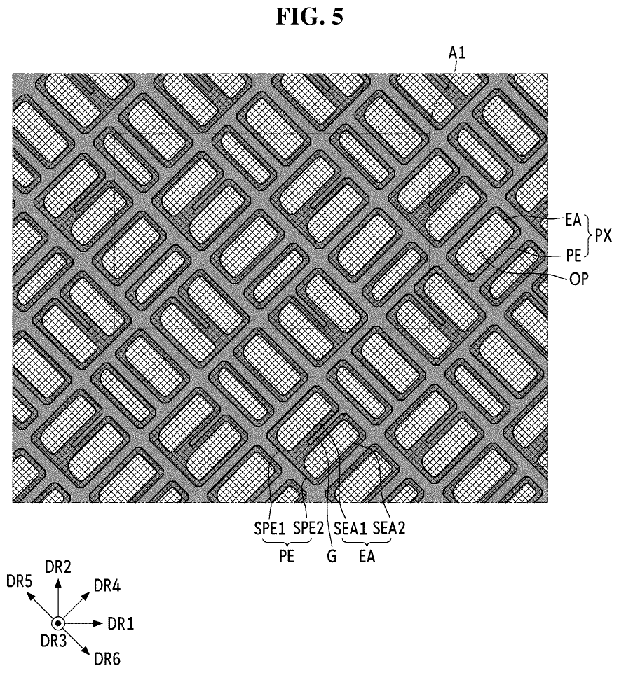

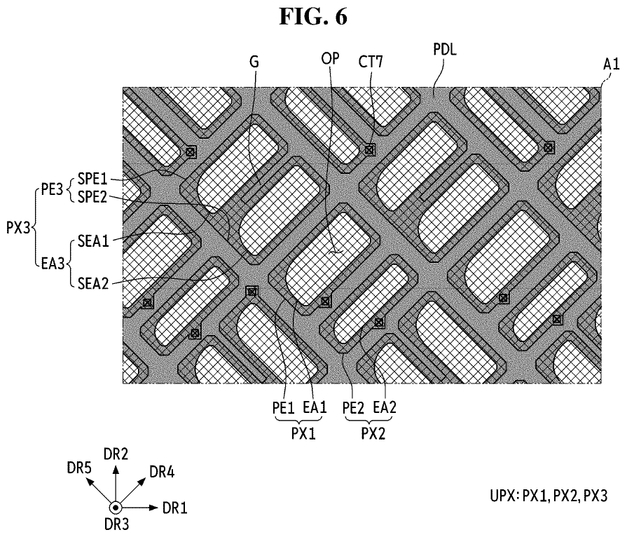

FIG. 5 is a plan view of the display device 10 according to an embodiment. FIG. 6 is an enlarged view of area A1 of FIG. 5. For example, FIG. 5 may be a plan view of a plurality of pixel electrodes PE and a plurality of emission areas EA located in the display area of FIG. 1.

As illustrated in FIG. 5, the emission areas EA may overlap the pixel electrodes PE, respectively. As described herein, the emission areas EA may be areas defined by the pixel defining layer PDL. For example, the pixel defining layer PDL may have a plurality of openings OP penetrating the pixel defining layer PDL in the third direction DR3, such that the plurality of openings OP may correspond to the emission areas EA that respectively expose the plurality of pixel electrodes PE. The pixel defining layer PDL of FIG. 5 may be a pixel defining layer having a black color. For example, the pixel defining layer PDL of FIG. 5 may include carbon.

The pixel electrode PE and the emission area EA that overlap each other may be included in the pixel PX. For example, the pixel PX may include the pixel electrode PE and the emission area EA overlapping the pixel electrode PE.

As illustrated in FIG. 6, a plurality of pixels PX1, PX2, and PX3 adjacent to each other and providing light of different colors may constitute a unit pixel UPX for displaying one unit image. For example, a first pixel PX1 including a first pixel electrode PE1 and a first emission area EA1 that overlap each other, a second pixel PX2 including a second pixel electrode PE2 and a second emission area EA2 that overlap each other, and a third pixel PX3 including a third pixel electrode PE3 and a third emission area EA3 that overlap each other may be located adjacent to each other along one direction (e.g., a fifth direction DR5), such that the first to third pixels PX1, PX2, and PX3 may form one unit pixel UPX. Here, the first pixel PX1 may provide light of the first color (e.g., light in a red wavelength band), the second pixel PX2 may provide light of the second color (e.g., light in a green wavelength band), and the third pixel PX3 may provide light of the third color (e.g., light in a blue wavelength band).

The pixels PX1, PX2, and PX3 included in the unit pixel UPX may include the pixel electrodes PE1, PE2, and PE3 of different sizes. For example, as illustrated in FIG. 6, the first to third pixel electrodes PE1, PE2, and PE3 of the first to third pixels PX1, PX2, and PX3 included in the unit pixel UPX may have different sizes. For example, the area of the first pixel electrode PE1 may be larger than the area of the second pixel electrode PE2 and smaller than the area of the third pixel electrode PE3.

Each of the plurality of pixel electrodes PE1, PE2, and PE3 may have a polygonal shape. For example, each of the plurality of pixel electrodes PE1, PE2, and PE3 may have a rectangular shape.

Some pixel electrodes among the plurality of pixel electrodes PE1, PE2, and PE3 may include two sub-pixel electrodes connected to each other. For example, as illustrated in FIG. 6, the third pixel electrode PE3 may include a first sub-pixel electrode SPE1 and a second sub-pixel electrode SPE2 having one sides connected to each other and the other sides separated by a gap G (or slit). The facing edges between the sub-pixel electrodes PE may be separated by the gap G (or slit). Through the gap G, outgas caused by organic materials in the first planarization layer VA1 and the second planarization layer VA2 may be smoothly discharged to the outside.

Each corner of the plurality of pixel electrodes PE1, PE2, and PE3 may have a shape cut in a diagonal shape. For example, each of the pixel electrodes PE1, PE2, and PE3 may have an octagonal shape. However, embodiments of the present disclosure are not limited thereto, and the shape of each of the plurality of pixel electrodes PE1, PE2, and PE3 may be variously modified.

The plurality of pixel electrodes PE1, PE2, and PE3 may extend in a diagonal direction. In an example in which a first side S1 of the display panel 100 extends along the second direction DR2 and a third side S3 of the display panel 100 extends along the first direction DR1, some pixel electrodes (e.g., the first pixel electrode PE1) among the plurality of pixel electrodes PE1, PE2, and PE3 may extend in a fourth direction DR4 between the first direction DR1 and the second direction DR2, and some other pixel electrodes among the plurality of the pixel electrodes PE1, PE2, and PE3 may extend in the fifth direction DR5 between the reverse direction (hereinafter, referred to as a first reverse direction) of the first direction DR1 and the second direction DR2. The angle between the first direction DR1 and the fourth direction DR4 may be 45 degrees, the angle between the second direction DR2 and the fifth direction DR5 may be 45 degrees, and the angle between the fourth direction DR4 and the fifth direction DR5 may be 90 degrees. However, the angles between the above-described directions are not limited to 45 degrees or 90 degrees and may be variously changed in accordance with one or more embodiments of the present disclosure.

The pixel electrode PE extending in the fourth direction DR4 may have a longer side in the fourth direction DR4 than in the fifth direction DR5. In an example in which a pixel electrode (e.g., the first pixel electrode PE1) extending in the fourth direction DR4 is defined as a first type pixel electrode, among the sides of the first type pixel electrode, a side parallel to the fourth direction DR4 may have a longer length than a side parallel to the fifth direction DR5.

A pixel electrode extending in the fifth direction DR5 may have a longer side in the fifth direction DR5 than in the fourth direction DR4. In an example in which a pixel electrode extending in the fifth direction DR5 is defined as a second type pixel electrode, among the sides of the second type pixel electrode, a side parallel to the fifth direction DR5 may have a longer length than a side parallel to the fourth direction DR4.

Each of the pixel electrodes PE1, PE2, and PE3 may be connected to the upper pixel connection electrode PCEb through the seventh contact hole CT7. For example, the first pixel electrode PE1 may be connected to the upper pixel connection electrode PCEb through the seventh contact hole CT7, the second pixel electrode PE2 may be connected to another upper pixel connection electrode PCEb through another seventh contact hole CT7, and the third pixel electrode PE3 may be connected to yet another upper pixel connection electrode PCEb through yet another seventh contact hole CT7.

Each of a plurality of emission areas EA1, EA2, and EA3 may have a polygonal shape. For example, each of the plurality of emission areas EA1, EA2, and EA3 may have a rectangular shape. At this time, the respective corners of the plurality of emission areas EA1, EA2, and EA3 may have a curved shape (or round shape).

Some emission areas among the plurality of emission areas EA1, EA2, and EA3 may include two sub-emission areas that are separated from each other. For example, as illustrated in FIG. 6, the third emission area EA3 may include a first sub-emission area SEA1 overlapping the first sub-pixel electrode SPE1 described herein and a second sub-emission area SEA2 overlapping the second sub-pixel electrode SPE2 described herein. A plurality of sub-emission areas SEA overlapping one pixel electrode may provide light of the same color. For example, the first sub-emission area SEA1 overlapping the first sub-pixel electrode SPE1 of the third pixel electrode PE3 and the second sub-emission area SEA2 overlapping the second sub-pixel electrode SPE2 of the third pixel electrode PE3 may provide light of the same color.

The plurality of emission areas EA1, EA2, and EA3 may extend in a diagonal direction. For example, some emission areas (e.g., the first emission area EA1) among the plurality of emission areas EA1, EA2, and EA3 may extend in the fourth direction DR4, and some other emission areas EA among the plurality of emission areas EA may extend in the fifth direction DR5. In other words, an emission area (e.g., EA1) overlapping a pixel electrode (e.g., the first type pixel electrode) extending in the fourth direction DR4 may extend in the fourth direction DR4, and an emission area overlapping a pixel electrode (e.g., the second type pixel electrode) extending in the fifth direction DR5 may extend in the fifth direction DR5.

An emission area (e.g., EA2) extending in the fourth direction DR4 may have a longer side in the fourth direction DR4 than in the fifth direction DR5. In an example in which the emission area EA extending in the fourth direction DR4 is defined as the first type emission area, the side parallel to the fourth direction DR4 among the sides of the first type emission area may have a longer length than the side parallel to the fifth direction DR5.

An emission area extending in the fifth direction DR5 may have a longer side in the fifth direction DR5 than in the fourth direction DR4. In an example in which an emission area extending in the fifth direction DR5 is defined as the second type emission area, the side parallel to the fifth direction DR5 among the sides of the second type emission area may have a longer length than the side parallel to the fourth direction DR4.

As described herein, each of the corners of the emission area EA may have a curved shape, such that, in this case, any one corner among all corners of the emission area EA may have a different radius of curvature from the other remaining corners. For example, among all corners of the emission area EA, the corner closest to the first side S1 of the display panel 100 may have the largest radius of curvature. Specifically, among all corners of the emission area EA, the corner closest to the first side S1 of the display panel 100 may have a larger radius of curvature than the other remaining corners. In other words, among all corners of the emission area EA, the corner closest to the first side S1 of the display panel 100 may have a smaller curvature than the other remaining corners.

Alternatively, among all corners of the emission area EA, a corner having a convex shape toward the first side S1 of the display panel 100 may have the largest radius of curvature. Specifically, among all corners of the emission area EA, a corner having a convex shape toward the first side S1 of the display panel 100 may have a larger radius of curvature than the other remaining corners. In other words, among all corners of the emission area EA, a corner having a convex shape toward the first side S1 of the display panel 100 may have a smaller curvature than the other remaining corners.

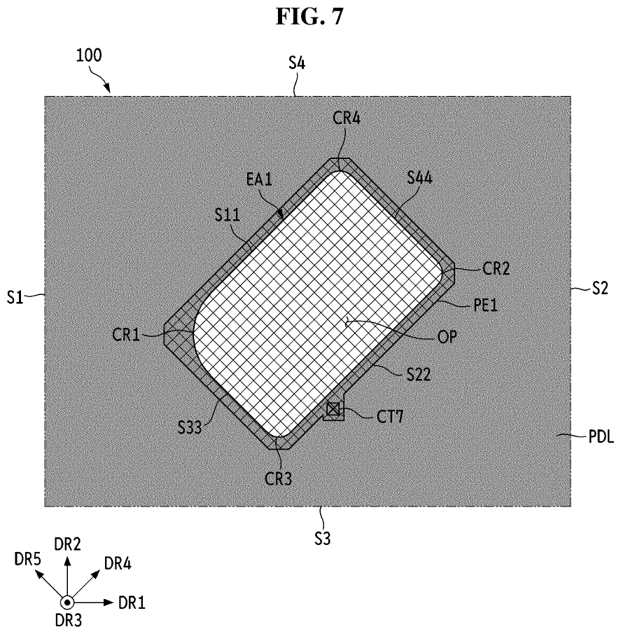

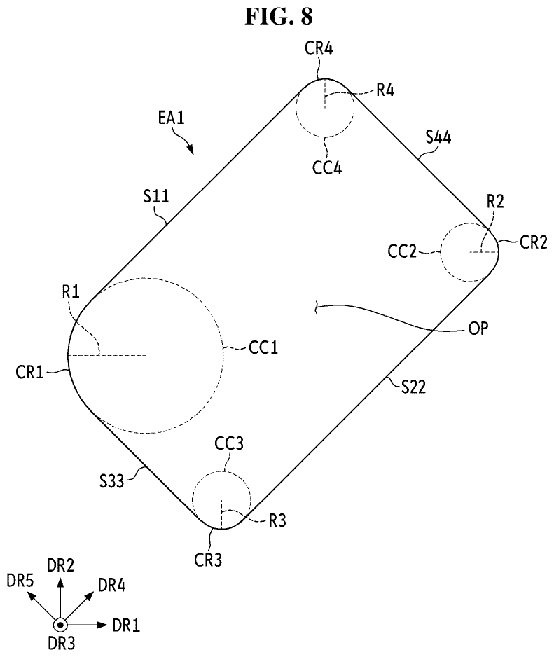

FIG. 7 is an enlarged view of the emission area EA according to an embodiment. For example, the emission area EA of FIG. 7 may be an enlarged view of the first emission area EA1 of FIG. 6 described herein. FIG. 8 is a view for describing the shape and radius of curvature of each corner of the emission area EA of FIG. 7.

As illustrated in FIG. 7, the first emission area EA1 may include a first side S11, a second side S22, a third side S33, a fourth side S44, a first corner CR1, a second corner CR2, a third corner CR3, and a fourth corner CR4 that are connected to each other.

The first side S11, the second side S22, the third side S33, the fourth side SS44, the first corner CR1, the second corner CR2, the third corner CR3, and the fourth corner CR4 of the first emission area EA1 may be inner walls of the opening OP defining the first emission area EA1. For example, the inner walls of the opening OP may include the first side S11, the second side S22, the third side S33, the fourth side S44, the first corner CR1, the second corner CR2, the third corner CR3, and the fourth corner CR4.

Each of the first side S11, the second side S22, the third side S33, and the fourth side S44 of the first emission area EA1 may have a shape of a straight line in plan view.

At least two of the first side S11, the second side S22, the third side S33, and the fourth side S44 of the first emission area EA1 may have different sizes (e.g., lengths). For example, each of the first side S11 and the second side S22 may have a longer length than the third side S33 (or the fourth side S44).

The first side S11, the second side S22, the third side S33, and the fourth side S44 of the first emission area EA1 may each extend in a diagonal direction. For example, each of the first side S11 and the second side S22 may extend in the fourth direction DR4, and each of the third side S33 and the fourth side S44 may extend in the fifth direction DR5.

The corner between two adjacent edges of the first emission area EA1 may have a curved (or round) shape. For example, the first corner CR1 between the first side S11 and the third side S33 that are adjacent may have a curved (or round) shape, the second corner CR2 between the second side S22 and the fourth side S44 that are adjacent may have a curved (or round) shape, the third corner CR3 between the second side S22 and the third side S33 that are adjacent may have a curved (or round) shape, and the fourth corner CR4 between the first side S11 and the fourth side S44 that are adjacent may have a curved (or round) shape. At this time, as illustrated in FIG. 8, the first corner CR1 of the first emission area EA1 may have a curved shape located along the perimeter of an imaginary first circle CC1 located within the first emission area EA1 and close to the first corner CR1, the second corner CR2 of the first emission area EA1 may have a curved shape located along the perimeter of an imaginary second circle CC2 located within the first emission area EA1 and close to the second corner CR2, the third corner CR3 of the first emission area EA1 may have a curved shape located along the perimeter of an imaginary third circle CC3 located within the first emission area EA1 and close to the third corner CR3, and the fourth corner CR4 of the first emission area EA1 may have a curved shape located along the perimeter of an imaginary fourth circle CC4 located within the first emission area EA1 and close to the fourth corner CR4.

The corners CR1, CR2, CR3, and CR4 of the first emission area EA1 may have curved convex shapes toward different directions. For example, as illustrated in FIG. 7, the first corner CR1 of the first emission area EA1 may have a curved convex shape in the first reverse direction, the second corner CR2 of the first emission area EA1 may have a curved convex shape in the first direction DR1, the third corner CR3 of the first emission area EA1 may have a curved convex shape in the reverse direction (hereinafter, referred to as a second reverse direction) of the second direction DR2, and the fourth corner CR4 of the first emission area EA1 may have a curved convex shape in the second direction DR2. Accordingly, the corners CR1, CR2, CR3, and CR4 of the emission area EA may have curved convex shapes toward the different sides S1, S2, S3, and S4 of the display panel 100. For example, the first corner CR1 of the first emission area EA1 may have a curved convex shape toward the first side S1 of the display panel 100 along the first reverse direction, the second corner CR2 of the first emission area EA1 may have a curved convex shape toward the second side S2 of the display panel 100 along the first direction DR1, the third corner CR3 of the first emission area EA1 may have a curved convex shape toward the third side S3 of the display panel 100 along the second reverse direction, and the fourth corner CR4 of the first emission area EA1 may have a curved convex shape toward the fourth side S4 of the display panel 100 along the second direction DR2.

As illustrated in FIG. 7, among all the corners CR1, CR2, CR3, and CR4 of the first emission area EA, the corner CR1 closest to the first side S1 of the display panel 100 may have the largest radius of curvature. In other words, among all the corners CR1, CR2, CR3, and CR4 of the first emission area EA1, the first corner CR1 closest to the first side S1 of the display panel 100 may have a larger radius of curvature than the other remaining corners CR2, CR3, and CR4. For example, as illustrated in FIGS. 7 and 8, among the first to fourth corners CR1, CR2, CR3, and CR4, the first corner CR1 having a convex shape toward the first side S1 of the display panel 100 is located closest to the first side S1 of the display panel 100, such that the first corner CR1 may have a larger radius of curvature R1 than the other corners CR2, CR3, and CR4. For example, the radius of curvature R1 of the first corner CR1 may be larger than a radius of curvature R2 of the second corner CR2. In other words, the first corner CR1 located along the perimeter of the first circle CC1 having the largest radius of curvature R1 among the first to fourth circles CC1, CC2, CC3, and CC4 may have a larger radius of curvature R1 than the second corner CR2 located along the perimeter of the second circle CC2. All of the radius of curvature R2 of the second corner CR2, a radius of curvature R3 of the third corner CR3, and a radius of curvature R4 of the fourth corner CR4 may be the same. For example, the second circle CC2, the third circle CC3, and the fourth circle CC4 may have the same radii of curvature R2, R3, and R4, such that the second corner CR2 located along the perimeter of the second circle CC2, the third corner CR3 located along the perimeter of the third circle CC3, and the fourth corner CR4 located along the perimeter of the fourth circle CC4 may have the same radii of curvature R2, R3, and R4, respectively. However, embodiments of the present disclosure are not limited thereto, and under the condition that the respective radii of curvature R2, R3, and R4 of the second corner CR2, the third corner CR3, and the fourth corner CR4 are smaller than the radius of curvature R1 of the first corner CR1, at least two corners among the second corner CR2, the third corner CR3, and the fourth corner CR4 may have different radii of curvature.

According to one embodiment, the radius of curvature of each of the second corner CR2, the third corner CR3, and the fourth corner CR4 may be smaller than the radius of curvature R1 of the first corner CR1. In this case, the respective areas of the emission areas EA1, EA2, and EA3 may increase, and in other words, the aperture ratio of the display device 10 may be improved. The higher the aperture ratio of the display device 10, the more light may be generated with the same power consumption in the display area DA of the same area. Accordingly, as the aperture ratio of the display device 10 increases, the power consumption of the display device 10 may decrease, and accordingly, the lifespan of the display device 10 may be improved.

Light incident on each of the sides S11, S22, S33, and S44 and each of the corners CR1, CR2, CR3, and CR4 of the first emission area EA1 of the display panel 100 may be reflected and scattered. Here, since each of the corners CR1, CR2, CR3, and CR4 of the first emission area EA1 has a curved shape, the amount of light reflected and scattered from each of the corners CR1, CR2, CR3, and CR4 of the first emission area EA1 may be smaller than the amount of light reflected and scattered from each of the sides S11, S22, S33, and S44 of the first emission area EA1. In some aspects, the first corner CR1 of the first emission area EA1 has the larger radius of curvature R1 than the other corners CR2, CR3, and CR4 of the first emission area EA1, such that the first emission area EA1 having such a structure may provide a relatively small amount of scattered light compared to an emission area (hereinafter, a comparative emission area) having all corners with the radii of curvature of the same magnitude. In other words, the amount of scattered light reflected from the first emission area EA1 having a first corner (e.g., a first corner having a larger radius of curvature than the radii of curvature of the other corners) with a relatively large curvature may be smaller than the amount of scattered light reflected from the comparative emission area. At this time, since the respective first corners CR1 of the emission areas EA are located closer to the first side S1 of the display panel 100 than the other corners CR2, CR3, and CR4, the amount of scattered light reflected from the emission areas EA and directed toward the first side S1 of the display panel 100 may be reduced.

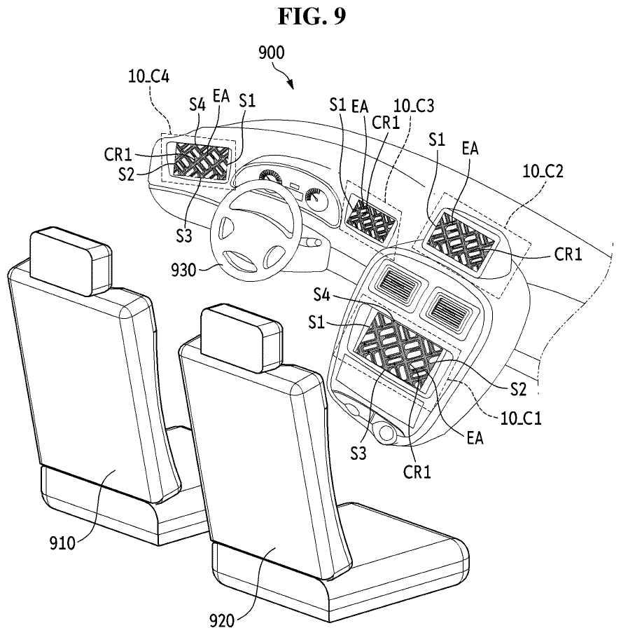

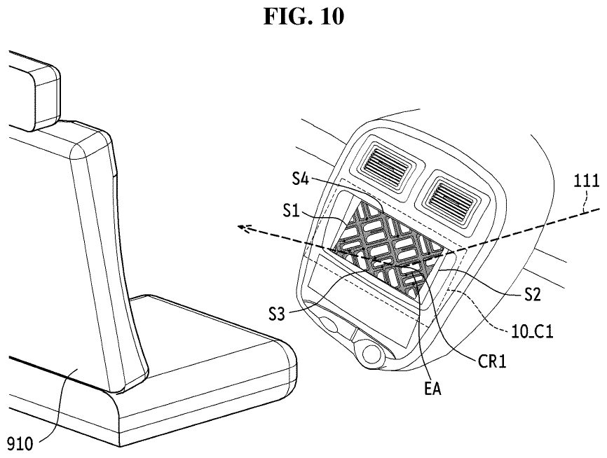

FIG. 9 is a diagram illustrating a portion of a vehicle 900 including the display device 10 according to an embodiment, and FIG. 10 is an enlarged view of a portion of FIG. 9.

As illustrated in FIG. 9, the display device 10 may be located in the vehicle 900. For example, a plurality of display devices 10_C1, 10_C2, 10_C3, and 10_C4 may be located in the vehicle 900. At this time, the first display device 10_C1 may be located at the center (e.g., the center between a driver's seat 910 and a passenger seat 920 of the vehicle 900) of the vehicle 900, the second display device 10_C2 may be located on the first display device 10_C1 at the center of the vehicle 900, the third display device 10_C3 may be located on the right side of the driver's seat 910 of the vehicle 900, and the fourth display device 10_C4 may be located on the left side of the driver's seat 910 of the vehicle 900. The driver's seat 910 of the vehicle 900 may face a steering wheel 930. Here, the third display device 10_C3 may be located on the right side of the steering wheel 930, and the fourth display device 10_C4 may be located on the left side of the steering wheel 930.

The first side S1 (e.g., the first side S1 of the display panel 100 of the first display device 10_C1) of the first display device 10_C1 may be located close to the driver's seat 910. Accordingly, among all the corners CR1, CR2, CR3, and CR4 of the emission area EA of the first display device 10_C1, the first corner CR1 having the largest radius of curvature R1 may be located close to the driver's seat 910. In other words, each of the first corners CR1 of all the emission areas EA of the first display device 10_C1 (e.g., the display panel 100 of the first display device 10_C1) may be located close to the driver's seat 910.

The first side S1 (e.g., the first side S1 of the display panel 100 of the second display device 10_C2) of the second display device 10_C2 may be located close to the driver's seat 910. Accordingly, among all the corners CR1, CR2, CR3, and CR4 of the emission area EA of the second display device 10_C2, the first corner CR1 having the largest radius of curvature R1 may be located close to the driver's seat 910. In other words, each of the first corners CR1 of all the emission areas EA of the second display device 10_C2 (e.g., the display panel 100 of the second display device 10_C2) may be located close to the driver's seat 910.

The first side S1 (e.g., the first side S1 of the display panel 100 of the third display device 10_C3) of the third display device 10_C3 may be located close to the driver's seat 910. Accordingly, among all the corners CR1, CR2, CR3, and CR4 of the emission area EA of the third display device 10_C3, the first corner CR1 having the largest radius of curvature R1 may be located close to the driver's seat 910. In other words, each of the first corners CR1 of all the emission areas EA of the third display device 10_C3 (e.g., the display panel 100 of the third display device 10_C3) may be located close to the driver's seat 910.

The first side S1 (e.g., the first side S1 of the display panel 100 of the fourth display device 10_C4) of the fourth display device 10_C4 may be located close to the driver's seat 910. Accordingly, among all the corners CR1, CR2, CR3, and CR4 of the emission area EA of the fourth display device 10_C4, the first corner CR1 having the largest radius of curvature may be located close to the driver's seat 910. In other words, each of the first corners CR1 of all the emission areas EA of the fourth display device 10_C4 (e.g., the display panel 100 of the fourth display device 10_C4) may be located close to the driver's seat 910. Here, the first side S1 of the fourth display device 10_C4 may be located to face the first side S1 of another display device 10. For example, the first side S1 of the fourth display device 10_C4 may face the first side S1 of the third display device 10_C3.

As illustrated in FIG. 10, light 111 from the outside may be incident on the first display device 10_C1. The light 111 incident on each of the sides S11, S22, S33, and S44 and each of the corners CR1, CR2, CR3, and CR4 of the emission area EA of the first display device 10_C1 may be reflected. Here, since each of the corners CR1, CR2, CR3, and CR4 of the emission area EA has a curved shape, the amount of light reflected and scattered from each of the corners CR1, CR2, CR3, and CR4 of the emission area EA may be smaller than the amount of light reflected and scattered from each of the sides S11, S22, S33, and S44 of the emission area EA. In some aspects, the first corner CR1 of the emission area EA has a larger radius of curvature than the other corners CR2, CR3, and CR4 of the emission area EA, such that the first emission area EA1 having such a structure may provide a relatively small amount of scattered light compared to an emission area (hereinafter, a comparative emission area) having all corners with the radii of curvature of the same magnitude. In other words, the amount of scattered light reflected from the first emission area EA1 having a first corner (e.g., a first corner having a larger radius of curvature than the radii of curvature of the other corners) with a relatively large curvature may be smaller than the amount of scattered light reflected from the comparative emission area. At this time, since each of the first corners CR1 of the emission areas EA is located closer to the driver's seat 910 than the other corners CR2, CR3, and CR4, the amount of scattered light reflected from the emission areas EA and directed toward the driver's seat 910 may be reduced. Accordingly, the amount of scattered light 111 directed toward the driver's seat 910 in the scattered light reflected from the first display device 10_C1 may be reduced. Accordingly, glare to the driver positioned in the driver's seat 910 may be minimized.

Likewise, the amount of scattered light reflected from the second display device 10_C2, the third display device 10_C3, and the fourth display device 10_C4 and directed toward the driver's seat 910 may be minimized.

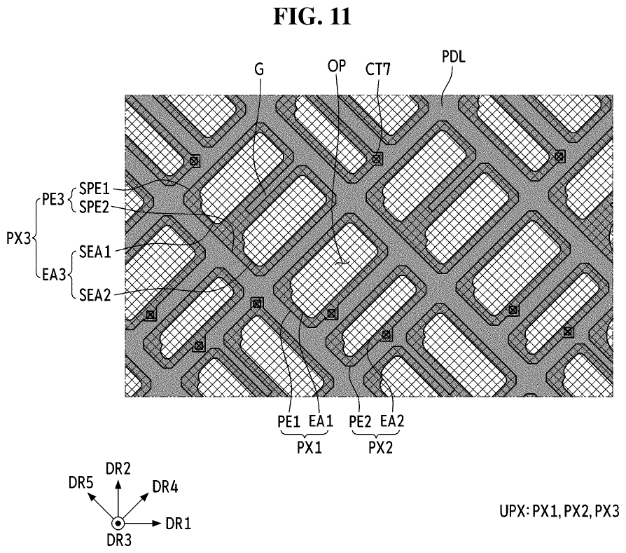

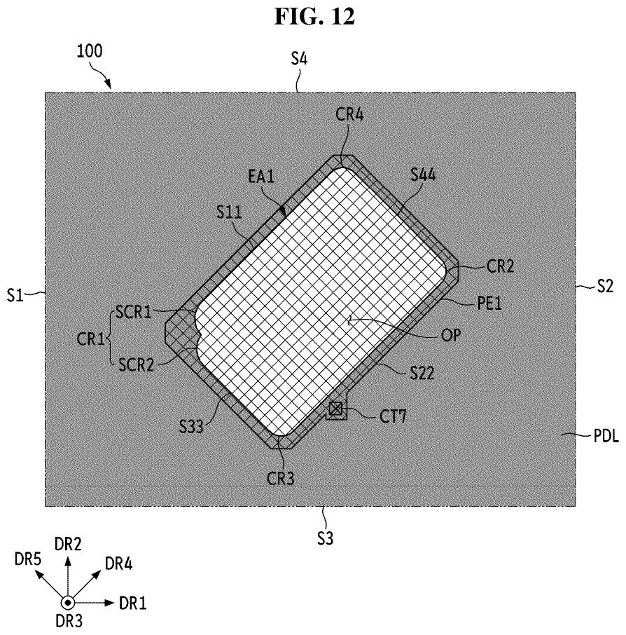

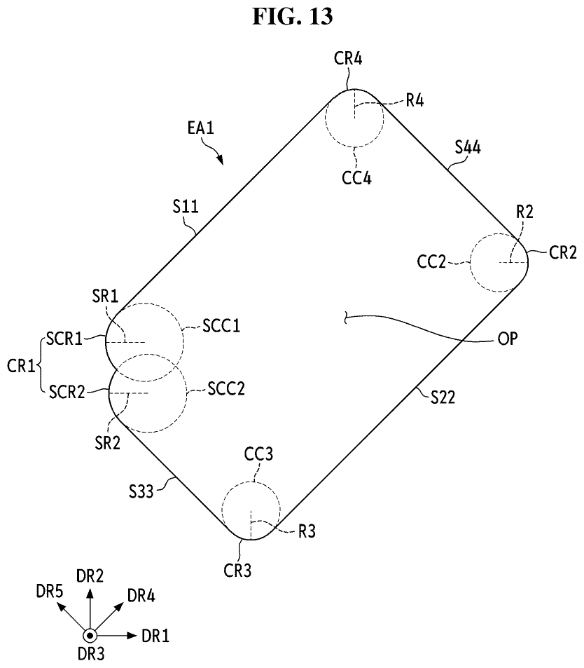

FIG. 11 is an enlarged view of the display device 10 according to an embodiment, and FIG. 12 is an enlarged view of the emission area EA according to an embodiment. For example, the emission area EA of FIG. 12 may be an enlarged view of the first emission area EA1 of FIG. 11 described herein. FIG. 13 is a view for describing the shape and radius of curvature of each corner of the first emission area EA1 of FIG. 12.

The display device 10 of FIGS. 11 to 13 differs from the display device 10 of FIGS. 6 to 8 described herein in that the respective first corners CR1 of the emission areas EA1, EA2, and EA3 include a plurality of sub-corners, such that the difference will be mainly described as follows.

As illustrated in FIGS. 11 to 13, the first corner CR1 of the first emission area EA1 may include a first sub-corner SCR1 and a second sub-corner SCR2. However, embodiments of the present disclosure are not limited thereto, and the first corner CR1 of the first emission area EA1 may include more than two sub-corners.

The sub-corners SCR1 and SCR2 of the first emission area EA1 may have curved convex shapes toward the same side of the display panel 100. For example, the first sub-corner SCR1 of the emission area EA may have a curved convex shape toward the first side S1 of the display panel 100, and the second sub-corner SCR2 of the emission area EA may have a curved convex shape toward the first side S1 of the display panel 100.

The second sub-corner SCR2 may be located adjacent to the first sub-corner SCR1. For example, the second sub-corner SCR2 and the first sub-corner SCR1 may be located adjacent to each other along the second direction DR2. The second sub-corner SCR2 may be connected to the first sub-corner SCR1.

The first sub-corner SCR1 may have a larger radius of curvature than the other corners, for example, the second corner CR2, the third corner CR3, and the fourth corner CR4.

The second sub-corner SCR2 may have a larger radius of curvature than the other corners, for example, the second corner CR2, the third corner CR3, and the fourth corner CR4.

The first sub-corner SCR1 and the second sub-corner SCR2 may have the same radius of curvature. However, embodiments of the present disclosure are not limited thereto, and under the condition that each of the radius of curvature of the first sub-corner SCR1 and the radius of curvature of the second sub-corner SCR2 are greater than each of the radii of curvature of the second corner CR2, the third corner CR3, and the fourth corner CR4 described herein, the radius of curvature of the first sub-corner SCR1 and the radius of curvature of the second sub-corner SCR2 may be different from each other. For example, the radius of curvature of the first sub-corner SCR1 may be smaller or larger than the radius of curvature of the second sub-corner SCR2.

As illustrated in FIG. 13, the first sub-corner SCR1 of the first emission area EA1 may have a curved shape located along the perimeter of an imaginary first sub-circle SCC1 located within the first emission area EA1 and close to the first sub-corner SCR1, and the second sub-corner SCR2 of the first emission area EA1 may have a curved shape located along the perimeter of an imaginary second sub-circle SCC2 located within the first emission area EA1 and close to the second sub-corner SCR2.

Likewise, the first corner CR1 of the second emission area EA2 may include the first sub-corner SCR1 and the second sub-corner SCR2. However, embodiments of the present disclosure are not limited thereto, and the first corner CR1 of the second emission area EA2 may include more than two sub-corners.

Likewise, the first corner CR1 of the third emission area EA3 may include the first sub-corner SCR1 and the second sub-corner SCR2. However, embodiments of the present disclosure are not limited thereto, and the first corner CR1 of the third emission area EA3 may include more than two sub-corners.

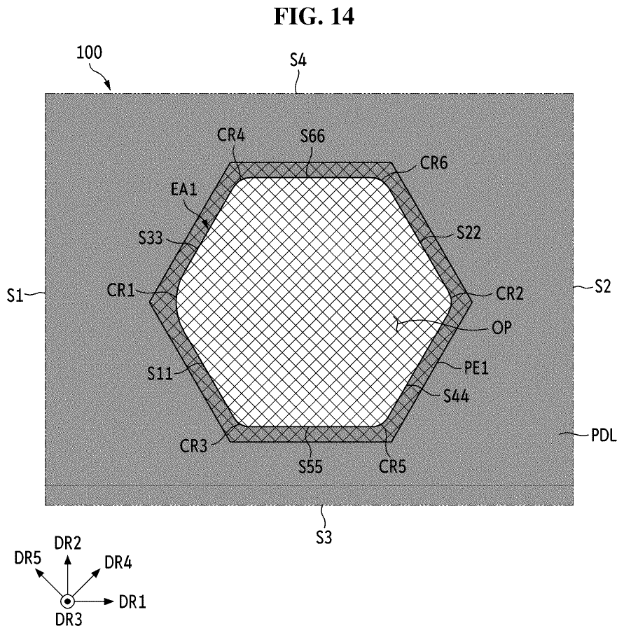

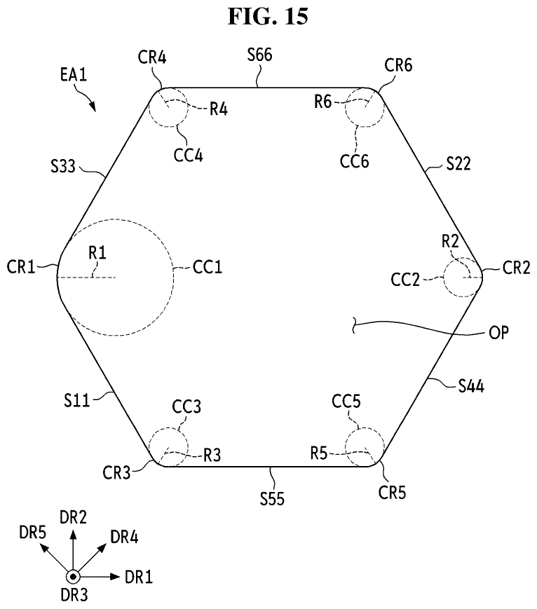

FIG. 14 is an enlarged view of the emission area EA of the display device 10 according to an embodiment, and FIG. 15 is a view for describing the shape and radius of curvature of each corner of the emission area EA of FIG. 14.

The display device 10 of FIGS. 14 and 15 differs from the display device 10 of FIGS. 6 to 8 described herein with respect to the shapes of the pixel electrode PE and the emission area EA, such that the difference will be mainly described as follows.

As illustrated in FIGS. 14 and 15, in plan view, each of the first pixel electrode PE1 and the first emission area EA1 may have a hexagonal shape.

As illustrated in FIG. 14, the first emission area EA1 may include the first side S11, the second side S22, the third side S33, the fourth side S44, a fifth side S55, and a sixth side S66, the first corner CR1, the second corner CR2, the third corner CR3, the fourth corner CR4, a fifth corner CR5, and a sixth corner CR6 that are connected to each other.

The first side S11, the second side S22, the third side S33, the fourth side S44, the fifth side S55, the sixth side S66, the first corner CR1, the second corner CR2, the third corner CR3, the fourth corner CR4, the fifth corner CR5, and the sixth corner CR6 of the first emission area EA1 may be inner walls of the opening OP defining the first emission area EA1. For example, the inner walls of the opening OP may include the first side S11, the second side S22, the third side S33, the fourth side S44, the fifth side S55, the sixth side S66, the first corner CR1, the second corner CR2, the third corner CR3, the fourth corner CR4, the fifth corner CR5, and the sixth corner CR6.

Each of the first side S11, the second side S22, the third side S33, the fourth side S44, the fifth side S55, and the sixth side S66 of the first emission area EA1 may have a shape of a straight line in plan view.

The first side S11, the second side S22, the third side S33, the fourth side S44, the fifth side S55, and the sixth side S66 of the first emission area EA1 may have the same size (e.g., length). However, embodiments of the present disclosure are not limited thereto, and for example, at least two sides among the first side S11, the second side S22, the third side S33, the fourth side S44, the fifth side S55, and the sixth side S66 of the first emission area EA1 may have different sizes (e.g., lengths).

The first side S11, the second side S22, the third side S33, and the fourth side S44 of the first emission area EA1 may each extend in a diagonal direction. For example, each of the first side S11 and the second side S22 may extend in the fifth direction DR5, and each of the third side S33 and the fourth side S44 may extend in the fourth direction DR4.

Each of the fifth side S55 and the sixth side S66 of the first emission area EA1 may extend in a horizontal direction. For example, each of the fifth side S55 and the sixth side S66 may extend in the first direction DR1.

The corner between two adjacent edges of the first emission area EA1 may have a curved (or round) shape. For example, the first corner CR1 between the first side S11 and the third side S33 that are adjacent may have a curved (or round) shape, the second corner CR2 between the second side S22 and the fourth side S44 that are adjacent may have a curved (or round) shape, the third corner CR3 between the first side S11 and the fifth side S55 that are adjacent may have a curved (or round) shape, the fourth corner CR4 between the third side S33 and the sixth side S66 that are adjacent may have a curved (or round) shape, the fifth corner CR5 between the fourth side S44 and the fifth side S55 that are adjacent may have a curved (or round) shape, and the sixth corner CR6 between the second side S22 and the sixth side S66 that are adjacent may have a curved (or round) shape. At this time, as illustrated in FIG. 15, the first corner CR1 of the first emission area EA1 may have a curved shape located along the perimeter of the imaginary first circle CC1 located within the emission area EA and close to the first corner CR1, the second corner CR2 of the first emission area EA1 may have a curved shape located along the perimeter of the imaginary second circle CC2 located within the first emission area EA1 and close to the second corner CR2, the third corner CR3 of the first emission area EA1 may have a curved shape located along the perimeter of the imaginary third circle CC3 located within the first emission area EA1 and close to the third corner CR3, the fourth corner CR4 of the first emission area EA1 may have a curved shape located along the perimeter of the imaginary fourth circle CC4 located within the first emission area EA1 and close to the fourth corner CR4, the fifth corner CR5 of the first emission area EA1 may have a curved shape located along the perimeter of an imaginary fifth circle CC5 located within the first emission area EA1 and close to the fifth corner CR5, and the sixth corner CR6 of the first emission area EA1 may have a curved shape located along the perimeter of an imaginary sixth circle CC6 located within the first emission area EA1 and close to the sixth corner CR6.

The corners CR1, CR2, CR3, CR4, CR5, and CR6 of the first emission area EA1 may have curved convex shapes toward different directions. For example, the first corner CR1 of the first emission area EA1 may have a curved convex shape in the first reverse direction, the second corner CR2 of the first emission area EA1 may have a curved convex shape in the first direction DR1, the third corner CR3 of the first emission area EA1 may have a curved convex shape in the reverse direction of the fourth direction DR4 (hereinafter, a fourth reverse direction), the fourth corner CR4 of the first emission area EA1 may have a curved convex shape in the fifth direction DR5, the fifth corner CR5 of the first emission area EA1 may have a curved convex shape in the reverse direction of the fifth direction DR5 (hereinafter, a fifth reverse direction), and the sixth corner CR6 of the first emission area EA1 may have a curved convex shape in the fourth direction DR4. Here, the first corner CR1 may have a curved convex shape toward the first side S1 of the display panel 100 along the first reverse direction, and the second corner CR2 may have a curved convex shape toward the second side S2 of the display panel 100 along the first direction DR1.

As illustrated in FIG. 14, among all the corners CR1, CR2, CR3, CR4, CR5, and CR6 of the first emission area EA1, the corner closest to the first side S1 of the display panel 100 may have the largest radius of curvature. In other words, among all the corners CR1, CR2, CR3, CR4, CR5, and CR6 of the first emission area EA1, the first corner CR1 closest to the first side S1 of the display panel 100 may have a larger radius of curvature R1 than the other remaining corners CR2, CR3, CR4, CR5, and CR6. For example, as illustrated in FIG. 15, among the first to sixth corners CR1, CR2, CR3, CR4, CR5, and CR6, the first corner CR1 having a convex shape toward the first side S1 of the display panel 100 is located closest to the first side S1 of the display panel 100, such that the first corner CR1 may have a larger radius of curvature R1 than the other corners CR2, CR3, CR4, CR5, and CR6. For example, the radius of curvature R1 of the first corner CR1 may be larger than the radius of curvature R2 of the second corner CR2. In other words, among the first to sixth circles CC1, CC2, CC3, CC4, CC5, and CC6, the first corner CR1 located along the perimeter of the first circle CC1 having the largest radius of curvature R1 may have a larger radius of curvature R1 than the second corner CR2 located along the perimeter of the second circle CC2. All of the radius of curvature R2 of the second corner CR2, the radius of curvature R3 of the third corner CR3, the radius of curvature R4 of the fourth corner CR4, a radius of curvature R5 of the fifth corner CR5, and a radius of curvature R6 of the sixth corner CR6 may be the same. For example, the second circle CC2, the third circle CC3, the fourth circle CC4, the fifth circle CC5, and the sixth circle CC6 may have the same radii of curvature, such that each of the second corner CR2 located along the perimeter of the second circle CC2, the third corner CR3 located along the perimeter of the third circle CC3, the fourth corner CR4 located along the perimeter of the fourth circle CC4, the fifth corner CR5 located along the perimeter of the fifth circle CC5, and the sixth corner CR6 located along the perimeter of the sixth circle CC6 may have the same radius of curvature. However, embodiments of the present disclosure are not limited thereto, and under the condition that the radius of curvature of each of the second corner CR2, the third corner CR3, the fourth corner CR4, the fifth corner CR5, and the sixth corner CR6 is smaller than the radius of curvature of the first corner CR1, at least two corners among the second corner CR2, the third corner CR3, the fourth corner CR4, the fifth corner CR5, and the sixth corner CR6 may have different radii of curvature.

Light incident on each of the sides S11 to S66 and each of the corners CR1 to CR6 of the first emission area EA1 of the display panel 100 may be reflected and scattered. Here, since each of the corners CR1 to CR6 of the first emission area EA has a curved shape, the amount of light reflected and scattered from each of the corners CR1 to CR6 of the emission area EA may be smaller than the amount of light reflected and scattered from each of the sides SS11 to SS66 of the first emission area EA1. In some aspects, the first corner CR1 of the first emission area EA1 has a larger radius of curvature than the other corners CR2 to CR6 of the emission area EA, such that the first emission area EA1 having such a structure may provide a relatively small amount of scattered light compared to an emission area (hereinafter, a comparative emission area) having all corners with the radii of curvature of the same magnitude. In other words, the amount of scattered light reflected from the first emission area EA1 having a first corner (e.g., a first corner having a larger radius of curvature than the radii of curvature of the other corners) with a relatively large curvature may be smaller than the amount of scattered light reflected from the comparative emission area. At this time, since the respective first corner CR1 of the first emission areas EA1 are located closer to the first side S1 of the display panel 100 than the other corners CR2 to CR6, the amount of scattered light reflected from the first emission areas EA1 and directed toward the first side S1 of the display panel 100 may be reduced.

The display device 10 of FIGS. 14 and 15 may be applied to the vehicle 900, as illustrated in FIGS. 9 and 10 described herein. At this time, the first corner CR1 of the first emission area EA1 of the display device 10 of FIGS. 14 and 15 may be located close to the first side S1 (or the first side S1 of the display panel 100 of the display device 10) of the display device 10. Accordingly, the amount of scattered light from the display device 10 directed toward the driver's seat 910 may be reduced, such that glare to the driver may be minimized.

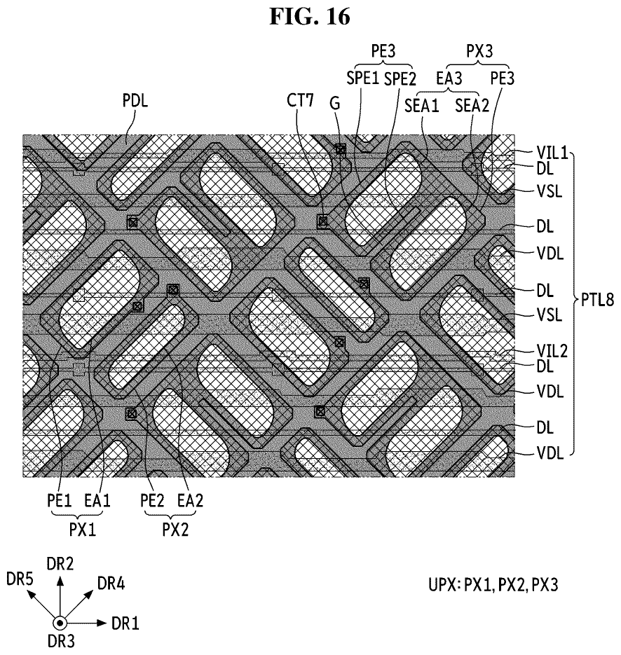

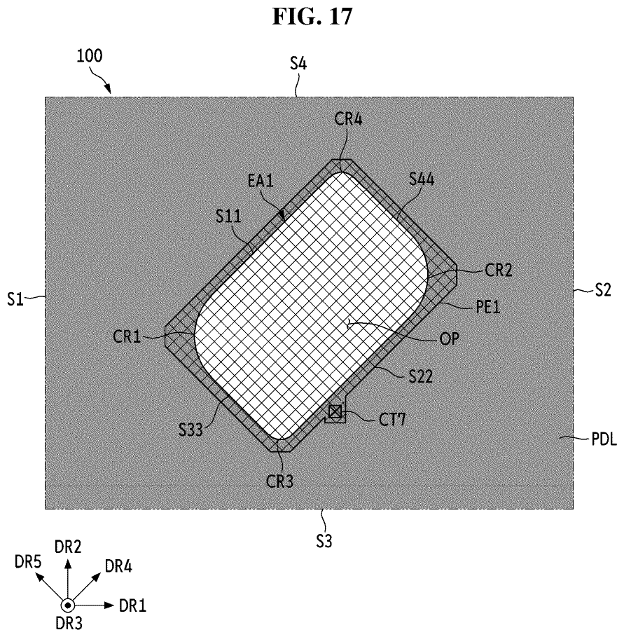

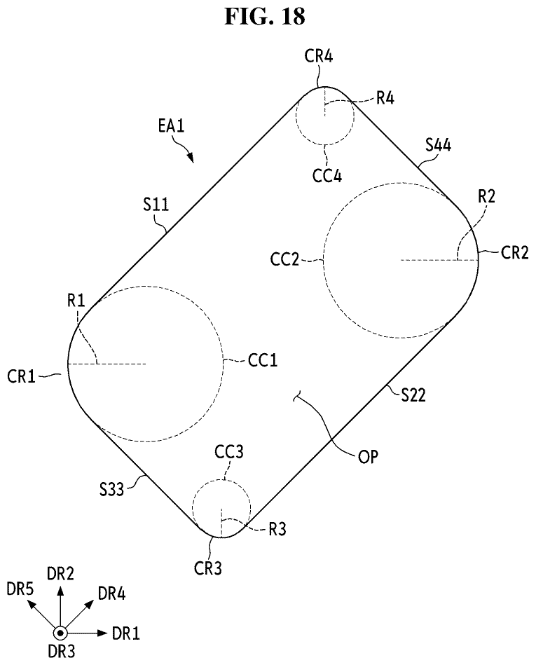

FIG. 16 is an enlarged view of the display device 10 according to an embodiment, and FIG. 17 is an enlarged view of the emission area EA according to an embodiment. For example, the emission area EA of FIG. 17 may be an enlarged view of the first emission area EA1 of FIG. 16 described herein. FIG. 18 is a view for describing the shape and radius of curvature of each corner of the first emission area EA1 of FIG. 17.

The display device 10 of FIGS. 16 to 18 differs from the display device 10 of FIGS. 6 to 8 described herein in that each of the first corner CR1 and the second corner CR2 of the first emission area EA1 has a larger radius of curvature than the other corners CR3 and CR4, such that the difference will be mainly described as follows.

As illustrated in FIGS. 16 to 18, the respective radii of curvature R1 and R2 of the first corner CR1 and the second corner CR2 of the first emission area EA1 may be larger than the radii of curvature R3 and R4 of the third corner CR3 and the fourth corner CR4 of the first emission area EA1. For example, the radius of curvature R1 of the first corner CR1 may be larger than the radius of curvature R3 of the third corner CR3 (or the fourth corner CR4), and the radius of curvature R2 of the second corner CR2 may be larger than the radius of curvature R3 of the third corner CR3 (or the fourth corner CR4).

The radius of curvature R2 of the second corner CR2 may be the same as the radius of curvature R1 of the first corner CR1. However, embodiments of the present disclosure are not limited thereto, and under the condition that the radius of curvature R2 of the second corner CR2 is greater than the radius of curvature R3 of the third corner CR3 (or the fourth corner CR4), the radius of curvature R2 of the second corner CR2 may be different from the radius of curvature R1 of the first corner CR1. For example, under the condition that the radius of curvature R2 of the second corner CR2 is greater than the radius of curvature R3 of the third corner CR3 (or fourth corner CR4), the radius of curvature R2 of the second corner CR2 may be greater than or less than the radius of curvature R1 of the first corner CR1.

Since the first corner CR1 and the second corner CR2 of the first emission area EA1 have larger radii of curvature than the other corners CR3 and CR4 of the first emission area EA1, the amount of scattered light reflected at the first corner CR1 and the amount of scattered light reflected at the second corner CR2 may be smaller than the amount of scattered light reflected at the other corners CR3 and CR4. At this time, since each first corner CR1 of the first emission area EA is located closer to the first side S1 of the display panel 100 than the other corners CR2, CR3, and CR4, the amount of scattered light reflected from the emission area EA and directed toward the first side S1 of the display panel 100 may be reduced. In some aspects, since the respective second corners CR2 of the first emission areas EA1 are located closer to the second side S2 of the display panel 100 than the other corners CR1, CR3, and CR4, the amount of scattered light reflected from the first emission area EA1 and directed toward the second side S2 of the display panel 100 may be reduced.

The respective radii of curvature R1 and R2 of the first corner CR1 and the second corner CR2 of the second emission area EA2 may be larger than the radii of curvature R3 and R4 of the third corner CR3 and the fourth corner CR4 of the second emission area EA2.

The respective radii of curvature R1 and R2 of the first corner CR1 and the second corner CR2 of the third emission area EA3 may be larger than the radii of curvature R3 and R4 of the third corner CR3 and the fourth corner CR4 of the third emission area EA3.

In some aspects, as illustrated in FIG. 16, among pattern layers located between the substrate SUB and the pixel electrode PE (see FIG. 4), or PE1 or PE2 or PE3 (see FIG. 16), the pattern layer (e.g., an eighth pattern layer PTL8) closest to the pixel electrode PE may extend in a convex direction of the first corner CR1 of the emission area (e.g., EA1). For example, the eighth pattern layer PTL8 may be located closest to the pixel electrode PE, such that the eighth pattern layer PTL8 extends in a direction parallel to a convex direction (e.g., a first reverse direction) of the first corner CR1 of the first emission area EA1. Here, the pixel defining layer PDL of FIGS. 16 to 18 may include, for example, an organic material. For example, the pixel defining layer PDL of FIGS. 16 to 18 may include polyimide.

The eighth pattern layer PTL8 may be provided in a plurality of numbers. A plurality of eighth pattern layers PTL8 may include, for example, the data line DL, and power lines (e.g., the driving voltage line VDL, the first initialization voltage line VIL1, the second initialization voltage line VIL2, and the common voltage line VSL). Here, the plurality of data lines DL may include a first data line, a second data line, and a third data line respectively connected to the first pixel PX1, the second pixel PX2, and the third pixel PX3 that provide light of different colors. Here, the first data line, the second data line, and the third data line are not connected to each other.

Each of the plurality of eighth pattern layers PTL8 may extend in the first direction DR1. In some aspects, the plurality of eighth pattern layers PTL8 may be spaced apart from each other along the second direction DR2. For example, each of the data line DL, the driving voltage line VDL, the first initialization voltage line VIL1, the second initialization voltage line VIL2, and the common voltage line VSL may extend in the first direction DR1. In some aspects, the data line DL, the driving voltage line VDL, the first initialization voltage line VIL1, the second initialization voltage line VIL2, and the common voltage line VSL may be spaced apart from each other along the second direction DR2.

As the eighth pattern layers PTL8 extend in the first direction DR1 in this way, scattered light reflected by the eighth pattern layers PTL8 and directed in the first direction DR1 and the first reverse direction may be minimized. For example, the area of the eighth pattern layers PTL8 seen in the first direction DR1 and the first reverse direction when the eighth pattern layers PTL8 extend in the first direction DR1 may be smaller than the area of the eighth pattern layers PTL8 seen in the first direction DR1 and the first reverse direction when the eighth pattern layers PTL8 extend in the second direction DR2. In an example in which the eighth pattern layers PTL8 extend in the first direction DR1 and the components of the eighth pattern layer PTL8 are spaced apart from each other along the second direction DR2, the area of the eighth pattern layers PTL8 seen in the first direction DR1 and the first reverse direction may be reduced due to the gap between the components of the eighth pattern layers PTL8 adjacent in the second direction DR2. In some embodiments, when the components of the eighth pattern layers PTL8 extend in the second direction DR2 and the components of the eighth pattern layers PTL8 are spaced apart from each other along the first direction DR1, the gap between the eighth pattern layers PTL8 is not seen in the first direction DR1 and the first reverse direction, and instead, all surfaces of the eighth pattern layers PTL8 along the respective extension directions of the eighth pattern layers PTL8 may be seen in the first direction DR1 and the first reverse direction. Accordingly, when the eighth pattern layers PTL8 extend in the second direction DR2, the amount of scattered light reflected in the first direction DR1 and the first reverse direction may increase.

In an example in which the pixel defining layer PDL includes an organic material that does not contain carbon, the display device 10 of FIGS. 16 to 18 may be advantageous in reducing scattered light by a metal layer (e.g., the eighth pattern layer PTL8) located directly below the pixel defining layer PDL.

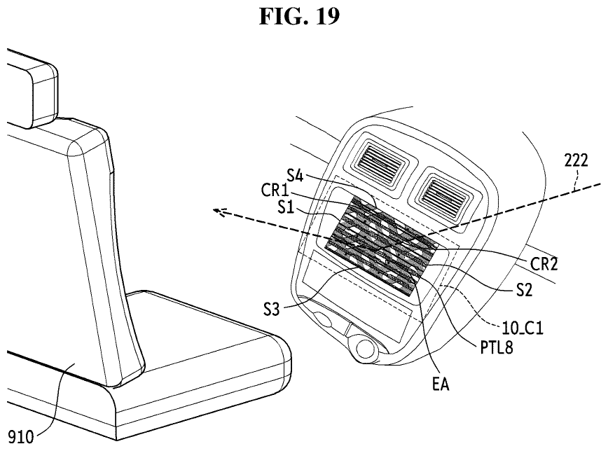

FIG. 19 is an enlarged view of a portion of the vehicle 900 including the display device 10 of FIGS. 16 to 18.

As illustrated in FIG. 19, the display device 10 may be located in the vehicle 900. For example, the display device 10 may be located in the center (e.g., the center between the driver's seat 910 and the passenger seat 920 of the vehicle 900) of the vehicle 900.

The first side S1 (e.g., the first side S1 of the display panel 100 of the display device 10) of the display device 10 may be located close to the driver's seat 910, and the second side S2 (e.g., the second side S2 of the display panel 100 of the display device 10) of the display device 10 may be located close to the passenger seat 920. Accordingly, the first corner CR1 of the first emission area EA1 of the display device 10 may be located close to the driver's seat 910, and the second corner CR2 of the first emission area EA1 of the display device 10 may be located close to the passenger seat 920. In some aspects, the eighth pattern layer PTL8 may extend in an imaginary line (e.g., an imaginary line extending in the first direction DR1) connecting the first side S1 and the second side S2 of the display device 10. In other words, each of the components (e.g., the data line DL, the driving voltage line VDL, the upper pixel connection electrode PCEb, the driving voltage line VDL, the first initialization voltage line VSL1, the second initialization voltage line VSL2, and the common voltage line VSL) of the eighth pattern layer PTL8 may extend in the first direction DR1. Accordingly, the amount of scattered light 222 directed toward the driver's seat 910 and passenger seat 920 in the scattered light reflected from the display device 10 may be reduced. Accordingly, glare to the driver positioned in the driver's seat 910 and the passenger positioned in the passenger seat 920 may be minimized.

The display device 10 of FIGS. 16 to 18 may be applied to the vehicle 900, as illustrated in FIGS. 9 and 10 described herein. At this time, the first corner CR1 of the emission area EA of the display device 10 of FIGS. 14 and 15 may be located close to the first side S1 (or the first side S1 of the display panel 100 of the display device 10) of the display device 10. Accordingly, the amount of scattered light from the display device 10 directed toward the driver's seat 910 may be reduced, such that glare to the driver may be minimized.

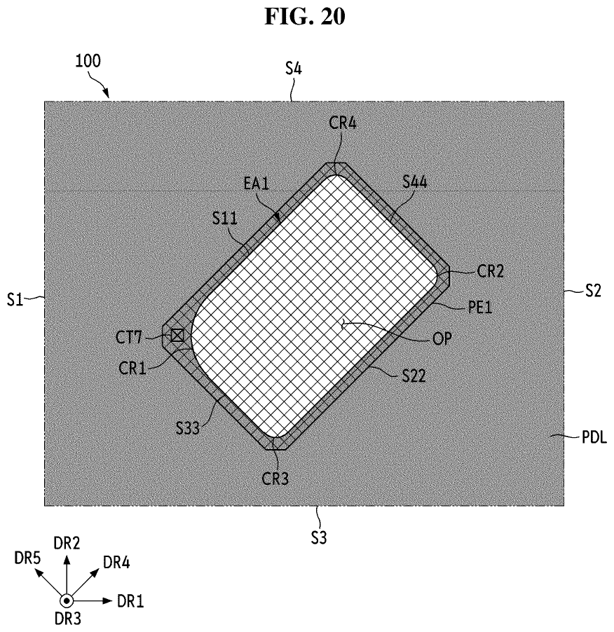

FIG. 20 is a plan view of the display device 10 according to an embodiment.

The display device 10 of FIG. 20 differs from the display device 10 of FIG. 7 described herein with respect to the position of the seventh contact hole CT7, such that the difference will be mainly described as follows.

As illustrated in FIG. 20, the seventh contact hole CT7 may be located adjacent to the first corner CR1 of the emission area EA. At this time, the seventh contact hole CT7 may be located such that the seventh contact hole CT7 overlaps the first pixel electrode PE1. In other words, the seventh contact hole CT7 may be located adjacent to the first corner CR1 of the first emission area EA1 and overlap the first pixel electrode PE1.

As illustrated in FIG. 20, in plan view, the seventh contact hole CT7 may be located between the first corner CR1 of the emission area EA and the corner (e.g., the corner of the first pixel electrode PE1 adjacent to the first corner CR1) of the first pixel electrode PE1.

Since the first corner CR1 of the first emission area EA1 has a larger radius of curvature than the other corners CR2 to CR4 of the first emission area EA1, an overlapping area between the pixel defining layer PDL and the first pixel electrode PE1 around the first corner CR1 may be larger than an overlapping area between the pixel defining layer PDL and the first pixel electrode PE1 around the other corners. Accordingly, the seventh contact hole CT7 may be located such that the seventh contact hole CT7 overlaps the first pixel electrode PE1. In this case, the distances among the adjacent pixel electrodes PE1, PE2, and PE3 may be designed to be closer, such that the resolution of the display device 10 may be improved.

In some aspects, the seventh contact hole CT7 described herein may be located adjacent to the first corner CR1 of the first emission area EA1 illustrated in FIG. 12, for example. In plan view, the seventh contact hole CT7 may be located between the first corner CR1 of the first emission area EA1 and the corner (e.g., the corner of the first pixel electrode PE1 adjacent to the first corner CR1) of the first pixel electrode PE1.

In some aspects, the seventh contact hole CT7 described herein may be located adjacent to the first corner CR1 of the first emission area EA1 illustrated in FIG. 14, for example. In plan view, the seventh contact hole CT7 may be located between the first corner CR1 of the first emission area EA1 and the corner (e.g., the corner of the first pixel electrode PE1 adjacent to the first corner CR1) of the first pixel electrode PE1.

In some aspects, the seventh contact hole CT7 described herein may be located adjacent to the second corner CR2 of the first emission area EA1 illustrated in FIG. 17, for example. In plan view, the seventh contact hole CT7 may be located between the second corner CR2 of the first emission area EA1 and the corner (e.g., the corner of the first pixel electrode PE1 adjacent to the second corner CR2) of the first pixel electrode PE1.

The display device 10 according to the embodiment may be applied to various electronic devices. An electronic device according to an embodiment may include the above-described display device 10 and may further include, in addition to the display device 10, a module or device having other additional functions.

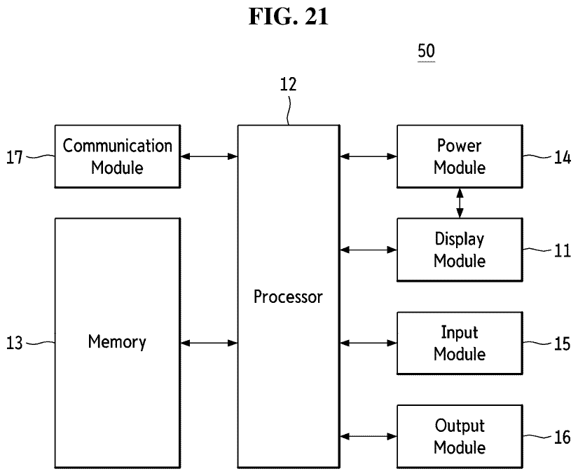

FIG. 21 is a block diagram of an electronic device according to an embodiment. Referring to FIG. 21, an electronic device 50 according to an embodiment may include a display module 11 (e.g., the display device 10), a processor 12, a memory 13, and a power module 14. The electronic device 50 may further include an input module 15, a non-visual output module 16, and/or a communication module 17.

The electronic device 50 may output various information in the form of images through the display module 11. In an example in which the processor 12 executes an application stored in the memory 13, image information provided by the application may be provided to a user through the display module 11. The power module 14 may include a power supply module, such as, for example, a power adapter or a battery device, and a power conversion module that converts the power supplied by the power supply module to generate the power for the operation of the electronic device 50. The input module 15 may provide input information to the processor 12 and/or the display module 11. The non-visual output module 16 may serve to receive information other than images, such as, for example, sound, haptics, luminescence, or the like, sent from the processor 12, and provide it to the user. The communication module 17 is a module responsible for the transmission and reception of information between the electronic device 50 and an external device, and the communication module 17 may include a receiver and a transmitter.

At least one of each of the components of the above-described electronic device 50 may be included in the display device according to the embodiments described herein. Further, some of individual modules functionally included in one module may be included in the display device and some others may be provided separately from the display device. For example, the display device may include the display module 11, whereas the processor 12, the memory 13 and the power module 14 may be provided in the form of other devices in the electronic device 50, other than the display device.

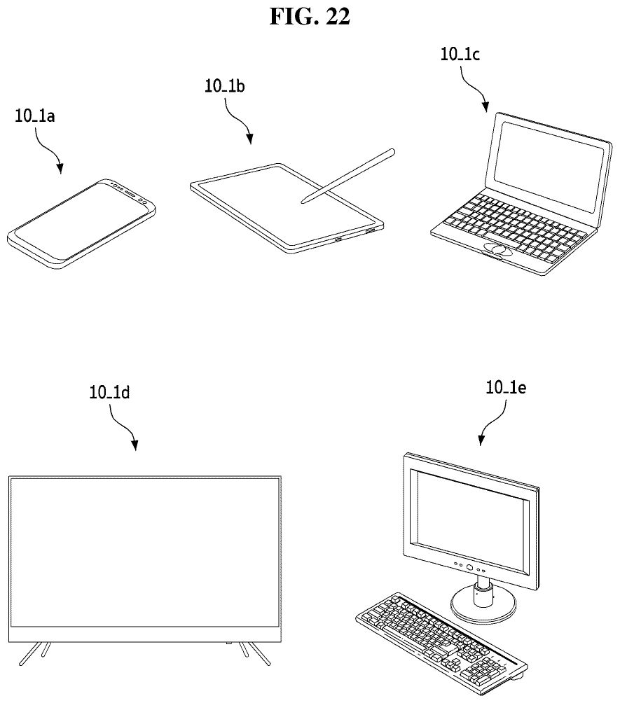

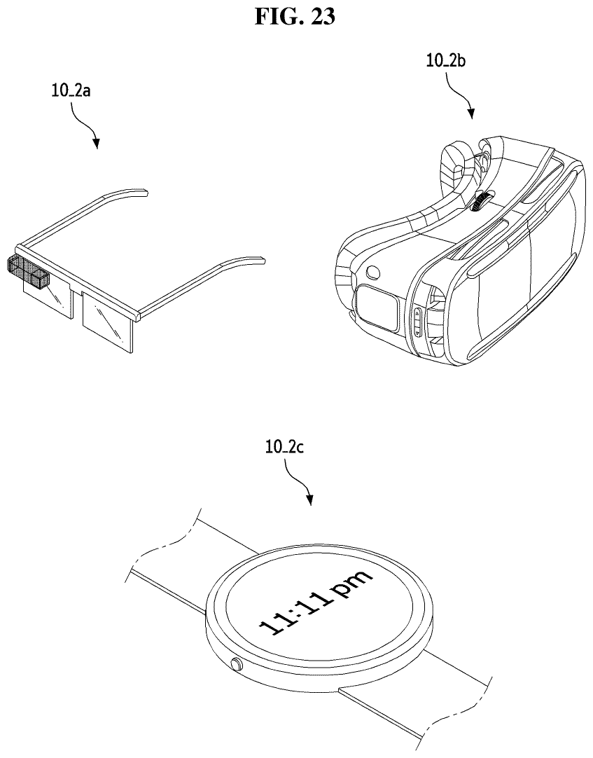

FIGS. 22 and 23 are schematic views of electronic devices according to various embodiments. FIGS. 22 and 23 illustrate examples of various electronic devices to which the display device 10 according to the above-described embodiments are applied.

FIG. 22 illustrates a smartphone 10_1a, a tablet PC 10_1b, a laptop 10_1c, a TV 10_1d, and a desk monitor 10_1e as examples of electronic devices.

The smartphone 10_1a may include a communication module and an input module such as, for example, a touch sensor, or the like, in addition to the display module 11. The smartphone 10_1a may process the information received through the communication module or input module and display the processed information through the display module of the display device.

Each of the tablet PC 10_1b, the laptop 10_1c, the TV 10_1d, and the desk monitor 10_1e may include a display and an input module, similarly to the smartphone 10_1a, and may further include a communication module in some cases.

FIG. 23 illustrates a case in which an electronic device including a display module is applied to a wearable electronic device. The wearable electronic device may be smart glasses 10_2a, a head mounted display 10_2b, a smart watch 10_2c, and the like.

The smart glasses 10_2a and the head mounted display 10_2b may include a display module that outputs a display image and a reflector that reflects the outputted display image to provide the outputted display image to the user's eyes, thereby providing the user with a virtual reality or augmented reality screen.

The smart watch 10_2c may include a biometric sensor as an input device and may provide biometric information recognized through the biometric sensor to the user through a display module.

A person having ordinary skill in the technical field to which this specification pertains will understand that this specification can be implemented in other specific forms without changing its technical idea or essential characteristics. Therefore, it should be understood that the embodiments described herein are examples in all respects and not restrictive. The scope of this specification is indicated by the scope of the patent claims described herein rather than the detailed description above, and all changes or modifications derived from the meaning and scope of the scope of the patent claims and their equivalent concepts should be interpreted as being included in the scope of this specification. This specification and drawings disclose example embodiments of this specification, and although specific terms are used, they are used in a general sense to easily explain the technical contents of this specification and to help understand the invention, and are not intended to limit the scope of this specification. In addition to the embodiments disclosed herein, it is obvious to a person having ordinary skill in the technical field to which this specification pertains that other modified examples based on the technical idea of this specification are possible.

What is claimed is:

1. A display device comprising:
a display panel; and
a display driver connected to the display panel,
wherein the display panel comprises:
a substrate;
a pixel electrode on the substrate;
a pixel defining layer located on the pixel electrode and having an emission area overlapping at least a part of the pixel electrode;
a light emitting layer on the pixel defining layer; and
a common electrode on the light emitting layer,
wherein:
the emission area comprises a first corner having a curved shape protruding convexly toward a first side of the display panel,
the first corner comprises a plurality of sub-corners connected to each other, and
each of the plurality of sub-corners has a curved shape protruding convexly toward the first side of the display panel.

2. The display device of claim 1, wherein a radius of curvature of each of the plurality of sub-corners is greater than radii of curvature of other corners of the emission area.

3. The display device of claim 1, wherein the plurality of sub-corners have a same radius of curvature as one another.

4. The display device of claim 1, wherein respective radii of curvature of corners of the emission area other than a first sub-corner and a second sub-corner of the plurality of sub-corners are equal to one other.

5. The display device of claim 1, further comprising a pattern layer disposed directly below the pixel electrode, between the substrate and the pixel electrode,
wherein in plan view, the pattern layer extends along a first direction perpendicular to an extension direction of the first side.

6. The display device of claim 5, wherein:
the display panel comprises:
the first side;
a second side facing the first side in the first direction;
a third side located between an end of the first side and an end of the second side; and
a fourth side facing the third side in a second direction and located between another end of the first side and another end of the second side, and the pattern layer extends along the first direction.

7. The display device of claim 6, wherein the display driver is located adjacent to the third side of the display panel.

8. The display device of claim 6, wherein the pattern layer is provided in plurality,
the plurality of pattern layers are arranged along a third direction intersecting the first direction, and
the first side of the display panel extends along the third direction.

9. The display device of claim 8, wherein the plurality of pattern layers each extend in the first direction.

10. The display device of claim 5, wherein:
a pixel comprising the pixel electrode and a pixel area is located in a display area of the display panel, and
the pattern layer comprises a data line and a power line connected to the pixel.

11. The display device of claim 10, wherein the data line and the power line each extend in the first direction.

12. The display device of claim 11, wherein the data line and the power line are arranged along the extension direction of the first side.

13. The display device of claim 1, wherein:
the pixel electrode is connected to a transistor on the substrate through a contact hole of an insulating layer, and
the contact hole is located adjacent to the first corner and overlaps the pixel electrode and the pixel defining layer.

14. The display device of claim 13, wherein in plan view, the contact hole is located between the first corner and a corner of the pixel electrode which is relatively close to the first corner.

15. A vehicle comprising:
a seat; and
a display device located adjacent to the seat,
wherein the display device comprises:
a display panel; and
a display driver connected to the display panel,
wherein the display panel comprises:
a substrate;
a pixel electrode on the substrate;
a pixel defining layer located on the pixel electrode and having an emission area overlapping at least a part of the pixel electrode;
a light emitting layer on the pixel defining layer; and
a common electrode on the light emitting layer,
wherein:
the emission area comprises a first corner having a curved shape protruding convexly toward a first side of the display panel,
the first corner comprises a plurality of sub-corners connected to each other, and
each of the plurality of sub-corners has a curved shape protruding convexly toward the first side of the display panel.

16. The vehicle of claim 15, wherein the first side of the display panel is located relatively close to the seat compared to other sides of the display panel.

17. The vehicle of claim 16, wherein the first side of the display panel is located close to the seat.
